(19) United States
(12) Patent Application Publication
(10) Pub. No.: US 2026/0113920 A1
(43) Pub. Date: Apr. 23, 2026

(54) SEMICONDUCTOR DEVICE

(71) Applicant: Taiwan Semiconductor Manufacturing Company, Ltd., Hsinchu (TW)

(72) Inventor: Jhon-Jhy LIAW, Zhudong Township (TW)

(21) Appl. No.: 18/918,438

(22) Filed: Oct. 17, 2024

(51) Int. Cl. H10B 10/00

(52) U.S. Cl. CPC H10B 10/125

(57) ABSTRACT

A semiconductor device includes a first transistor cell having a first L-shape cell boundary, a first active area having a first channel layer with a first width in a first direction, and a second active area having a second channel layer with a second width in the first direction. The first width is different from the second width, and at least two first back-side metal conductors are electrically connected to the first transistor cell.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, fin field-effect transistors (FinFETs) and gate-all-around (GAA) transistors have been incorporated into semiconductor devices (including, for example, static random-access memory, or SRAM, cells) to reduce chip footprint while maintaining reasonable processing margins.

However, as semiconductor devices continue to be scaled down, interconnection routing for semiconductor devices uses too many routing resources and therefore impacts the cell scaling as well as memory performance. Accordingly, although existing technologies for fabricating semiconductor devices have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIG. 2 illustrates a circuit diagram for a SRAM cell that can be implemented in an array of two-port SRAM cells in the memory region of FIG. 1, in accordance with some alternative embodiments of the present disclosure.

FIG. 3 is a perspective view of a GAA transistor in the SRAM cell, in accordance with some embodiments of the present disclosure.

FIG. 4 shows a cross-sectional view of a semiconductor device for illustrating a front-side interconnection structure and a back-side interconnection structure, in accordance with some embodiments of the present disclosure.

FIGS. 5A and 5B illustrate top views (or layouts) of features in a device region and a front-side interconnection structure of two adjacent SRAM cells in a portion of an array that can be one embodiment of the SRAM cells implemented in the memory region, in accordance with some embodiments of the present disclosure.

FIG. 5C illustrates a top view (or a layout) of the features in the device region and a back-side interconnection structure of the two adjacent SRAM cells in the portion of the array that can be one embodiment of the SRAM cells implemented in the memory region, in accordance with some embodiments of the present disclosure.

FIG. 5D is an X-Z cross-sectional view of the array along a line A-A′ in FIGS. 5A to 5C, in accordance with some embodiments of the present disclosure.

FIG. 5E is an X-Z cross-sectional view of the array along a line B-B′ in FIGS. 5A to 5C, in accordance with some embodiments of the present disclosure.

FIG. 5F is a Y-Z cross-sectional view of the array along a line C-C′ in FIGS. 5A to 5C, in accordance with some embodiments of the present disclosure.

FIG. 5G is a Y-Z cross-sectional view of the array along a line D-D′ in FIGS. 5A to 5C, in accordance with some embodiments of the present disclosure.

FIGS. 6A and 6B illustrate top views (or layouts) of features in a device region and a front-side interconnection structure of two adjacent SRAM cells in a portion of an array that can be one embodiment of the SRAM cells implemented in the memory region, in accordance with some alternative embodiments of the present disclosure.

FIG. 6C illustrates a top view (or a layout) of the features in the device region and a back-side interconnection structure of the two adjacent SRAM cells in the portion of the array that can be one embodiment of the SRAM cells implemented in the memory region, in accordance with some alternative embodiments of the present disclosure.

FIG. 6D is an X-Z cross-sectional view of the array along a line E-E′ in FIGS. 6A to 6C, in accordance with some alternative embodiments of the present disclosure.

FIGS. 7A, 7B, and 7C illustrate top views (or layouts) of features in a device region and a front-side interconnection structure of two adjacent SRAM cells in a portion of an array that can be one embodiment of the SRAM cells implemented in the memory region, in accordance with some alternative embodiments of the present disclosure.

FIG. 7D illustrates a top view (or a layout) of the features in the device region and a back-side interconnection structure of the two adjacent SRAM cells in the portion of the array that can be one embodiment of the SRAM cells implemented in the memory region, in accordance with some alternative embodiments of the present disclosure.

FIG. 7E is an X-Z cross-sectional view of the array along a line F-F′ in FIGS. 7A to 7D, in accordance with some alternative embodiments of the present disclosure.

FIGS. 8A and 8B illustrate top views (or layouts) of features in a device region and a front-side interconnection structure of two adjacent SRAM cells in a portion of an array that can be one embodiment of the SRAM cells implemented in the memory region, in accordance with some alternative embodiments of the present disclosure.

FIG. 8C illustrates a top view (or a layout) of the features in the device region and a back-side interconnection structure of the two adjacent SRAM cells in the portion of the array that can be one embodiment of the SRAM cells implemented in the memory region, in accordance with some alternative embodiments of the present disclosure.

FIG. 8D is an X-Z cross-sectional view of the array along a line G-G′ in FIGS. 8A to 8C, in accordance with some alternative embodiments of the present disclosure.

FIGS. 9A and 9B illustrate top views (or layouts) of features in a device region and a front-side interconnection structure of two adjacent SRAM cells in a portion of an array that can be one embodiment of the SRAM cells implemented in the memory region, in accordance with some alternative embodiments of the present disclosure.

FIG. 9C illustrates a top view (or a layout) of the features in the device region and a back-side interconnection structure of the two adjacent SRAM cells in the portion of the array that can be one embodiment of the SRAM cells implemented in the memory region, in accordance with some alternative embodiments of the present disclosure.

FIG. 9D is an X-Z cross-sectional view of the array along a line H-H′ in FIGS. 9A to 9C, in accordance with some alternative embodiments of the present disclosure.

FIGS. 10 and 11 each illustrates one embodiment of a portion of the array, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to static random-access memory (SRAM) cells having field-effect transistors (FETs), such as three-dimensional gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure also relates to layouts and structures thereof of semiconductor devices. More particularly, the present disclosure relates to two-port SRAM cell layout designs and structures. The present disclosure provides a compact two-port SRAM cell design having a width of four gate pitches (the so-called four-gate-pitch SRAM cell) and with multiple metal layers with metal conductors (or tracks) used for connections and over transistors. Transistors such as gate-all-around (GAA) transistors forming the two-port SRAM cell are fabricated over a substrate. Some of the metal conductors, such as read bit-line conductors, write bit-line conductors, and write bit-line-bar (also referred to as complementary bit-line) conductors, are fabricated in the lowest metal layer in the front-side interconnection structure. Some of the metal conductors, such as VDD conductors and VSS conductors, are fabricated in the lowest metal layer in the back-side interconnection structure. Other metal conductors, such as write word-line conductors and read word-line conductors, are fabricated in higher metal layers in the front-side interconnection structure.

Therefore, the space at the front-side interconnection structure are relieved to reduce the routing complexity due to some metal conductors are in the back-side interconnection structure. Furthermore, the metal conductors can be made wider to have low resistance, thereby improving the performance of the semiconductor devices. The read bit-line conductors, the write bit-line conductors, the write bit-line-bar, the VDD conductors, and the VSS conductors fabricated in the lowest metal layer (in the front-side interconnection structure or the back-side interconnection structure) have lower capacitance, thereby improving the performance of the semiconductor devices. The SRAM layout according to the present disclosure is process friendly and lithography friendly, enabling better process margin.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include an array of two-port SRAM cells each constructed by eight GAA transistors, in which two two-port SRAM cells in adjacent two rows have read bit-line conductors, write bit-line conductors, and write bit-line-bar conductors in the lowest metal layer in the front-side interconnection structure, and VDD conductors and VSS conductors in the lowest metal layer in the back-side interconnection structure, that can improve cell performance and reduce the routing complexity of the two-port SRAM cell. The details of the present disclosure are described below in conjunction with the accompanying drawings, which illustrate the layout and structure of circuit cells, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated. The X-direction, the Y-direction, and the Z-direction can be arbitrarily referred to as the first direction, the second direction, or the third direction in the order of appearance. For example, the Z-direction can be referred to as the first direction, and one of the X-direction and the Y-direction can be referred to as the second direction, and the other one of the X-direction and the Y-direction can be referred to as the third direction.

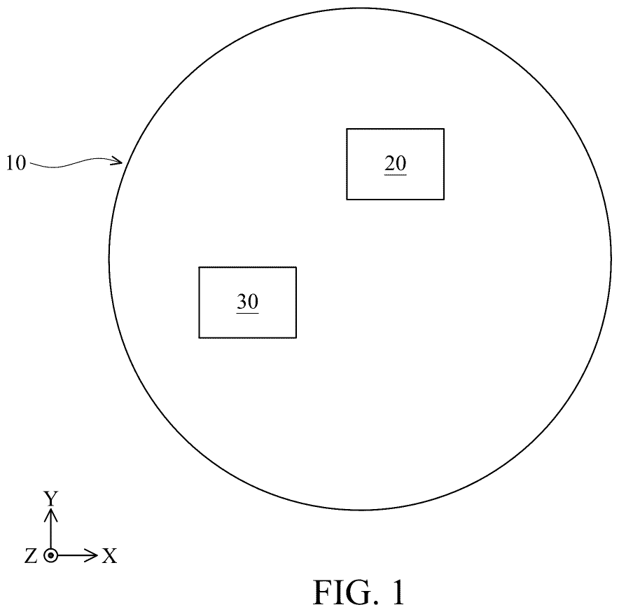

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or combinations thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable semiconductor devices, or a combination thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or a combination thereof.

The logic region 30 can include an array of circuit cells having various logic cells or standard (STD) cells. The logic cells or STD cells may include transistors and interconnection structures that combine to provide a logic device and/or a logic function, such as an inverter, an AND, a NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

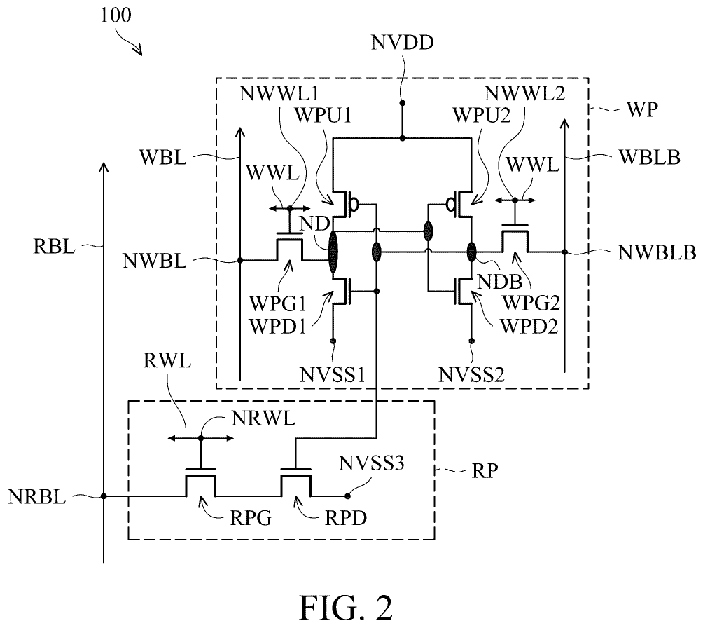

FIG. 2 is a circuit diagram for an SRAM cell 100 that can be implemented in an array of two-port SRAM cells in the memory region 20 of FIG. 1, in accordance with some alternative embodiments of the present disclosure. The SRAM cell 100 includes a write-port circuit WP having data nodes ND and NDB, a read-port circuit RP coupled with data node ND. The SRAM cell 100 may also be referred to as two-port SRAM cells due to the SRAM cell 100 has two-port of write-port circuit and the read-port circuit, as shown in FIG. 2.

The SRAM cell 100 may in a row of an array of SRAM cells. Take the SRAM cell 100 as an example below to illustrate the operations and the circuit of the SRAM cell 100. The write-port circuit WP includes two p-type transistors, such as write-port pull-up (WPU) transistors WPU1 and WPU2, and four n-type transistors, such as write-port pull-down (WPD) transistors WPD1 and WPD2 and write-port pass-gate (WPG) transistors WPG1 and WPG2. The WPU transistor WPU1, the WPU transistor WPU2, the WPD transistor WPD1, and the WPD transistor WPD2 form a cross latch having two cross-coupled inverters. The WPU transistor WPU1 and the WPD transistor WPD1 form a first inverter while the WPU transistor WPU2 and the WPD transistor WPD2 form a second inverter.

Drains of the WPU transistor WPU1 and the WPD transistor WPD1 are coupled together and form data node ND. Drains of the WPU transistor WPU2 and the WPD transistor WPD2 are coupled together and form data node NDB. Gates of the WPU transistor WPU1 and the WPD transistor WPD1 are coupled together and to drains of the WPU transistor WPU2 and the WPD transistor WPD2. Gates of the WPU transistor WPU2 and the WPD transistor WPD2 are coupled together and to drains of the WPU transistor WPU1 and the WPD transistor WPD1.

Sources of the WPU transistor WPU1 and the WPU transistor WPU2 are coupled together and to a supply voltage node NVDD. In some embodiments, the supply voltage nodes NVDD is configured to receive a supply voltage VDD. Source of the WPD transistor WPD1 is coupled with a reference voltage node NVSS1, and source of the WPD transistor WPD2 is coupled with a reference voltage node NVSS2. In some embodiments, reference voltage node NVSS1 and reference voltage node NVSS2 are electrically coupled together and configured to receive a reference voltage VSS.

The WPG transistor WPG1 functions as a pass gate between the data node ND and a write bit-line WBL, and the WPG transistor WPG2 functions as a pass gate between the data node NDB and a write bit-line-bar WBLB. A drain of the WPG transistor WPG1 is referred to as a write bit-line node NWBL and electrically coupled with the write bit-line WBL. A source of the WPG transistor WPG1 is electrically coupled with the data node ND. A drain of the WPG transistor WPG2 is referred to as a write bit-line-bar node NWBLB and electrically coupled with the write bit-line-bar WBLB. A source of the WPG transistor WPG2 is electrically coupled with the data node NDB. A gate of the WPG transistor WPG1 is referred to as a write word-line node NWWL1, a gate of the WPG transistor WPG2 is referred to as a write word-line node NWWL2, and write word-line nodes NWWL1 and NWWL2 are electrically coupled with a write word-line WWL.

In some embodiments, the write bit-line-bars WBLB and write bit-lines WBL are coupled to each drain of the WPG transistors WPG1 and WPG2 of memory cells in the same column of the array of the SRAM cells, and write word-line WWL is coupled to each gate of the WPG transistors WPG1 and WPG2 of memory cells in the same row of the array of the SRAM cells.

In a write operation of the SRAM cell 100 using the write-port circuit WP, data to be written to the SRAM cell 100 is applied to the write bit-line WBL and the write bit-line-bar WBLB. The write word-line WWL is then activated to turn on the WPG transistors WPG1 and WPG2. As a result, the data on the write bit-line WBL and the write bit-line-bar WBLB is transferred to and is stored in corresponding data nodes ND and NDB.

The read-port circuit RP includes two n-type transistors, such as read-port pull-down (RPD) transistor RPD and read-port pass-gate (RPG) transistor RPG. A source of the RPD transistor RPD is coupled with a reference voltage node NVSS3. In some embodiments, the reference voltage node NVSS3 is configured to receive the reference voltage VSS. A gate of the RPD transistor RPD is coupled with the data node NDB and the gates of the WPU transistor WPU1 and the WPD transistor WPD1. A drain of the RPD transistor RPD is coupled with a source of the RPG transistor RPG. A drain of the RPG transistor RPG is referred to as a read bit-line node NRBL and electrically coupled with a read bit-line RBL. A gate of the RPG transistor RPG is referred to as a read word-line node NRWL and electrically coupled with a read word-line RWL.

In a read operation of the SRAM cell 100 using the read-port circuit RP, the read bit-line RBL is pre-charged with a high logical value. The read word-line RWL is activated with a high logical value to turn on the RPG transistor RPG. The data stored in data node NDB turns on or off the RPD transistor RPD. For example, if data node NDB stores a high logical value, the RPD transistor RPD is turned on. The turned-on RPG transistor RPG and the turned-on RPD transistor RPD then pull read bit-line RBL to the reference voltage VSS or a low logical value at the source of the RPD transistor RPD. On the other hand, if the data node NDB stores a low logical value, the RPD transistor RPD is turned off and operates as an open circuit. As a result, the read bit-line RBL remains at the pre-charged high logical value. Detecting a logical value on the read bit-line RBL therefore reveals the logical value stored in the data node NDB.

Although not shown in FIG. 2, in some embodiments, the gate of the RPD transistor RPD is coupled with the data node ND and the gates of the WPU transistor WPU2 and the WPD transistor WPD2. In such case, in the read operation of the SRAM cell 100 using the read-port circuit RP, the data stored in data node ND turns on or off the RPD transistor RPD. For example, if data node ND stores a high logical value, the RPD transistor RPD is turned on. The turned-on RPG transistor RPG and the turned-on RPD transistor RPD then pull read bit-line RBL to the reference voltage VSS or a low logical value at the source of the RPD transistor RPD. On the other hand, if the data node ND stores a low logical value, the RPD transistor RPD is turned off and operates as an open circuit. As a result, the read bit-line RBL remains at the pre-charged high logical value. Detecting a logical value on the read bit-line RBL therefore reveals the logical value stored in the data node ND.

In the present embodiments, adjacent two SRAM cells in the adjacent two rows are abutted with each other share the same read bit-line. In other words, the read bit-line node NRBL of the RPG transistor RPG of one SRAM cell 100 in one row and the read bit-line node NRBL of the RPG transistor RPG of another SRAM cell 100 in adjacent row are further coupled together and to the read bit-line RBL. In other word, two SRAM cells 100 share the read bit-line RBL. In some embodiments, the SRAM cell 100 shown in FIG. 2 has a total of eight transistors (including the WPU transistors WPU1 and WPU2, the WPD transistors WPD1 and WPD2, the WPG transistors WPG1 and WPG2, and the RPD transistors RPD and RPD), such that the SRAM cell 100 be referred to as 8T SRAM cell.

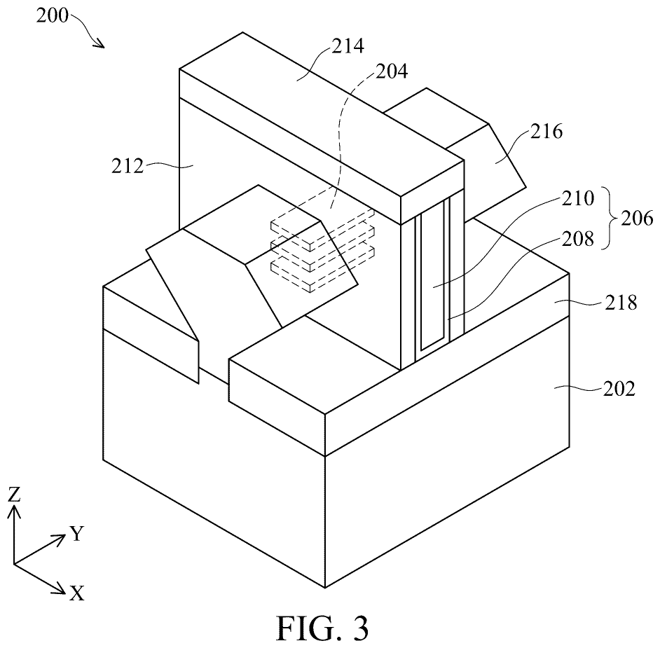

The SRAM cell 100 discussed above is constructed by transistors, such that the SRAM cell 100 may also be referred to as the transistor cell. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 3. However, it should be understood that the application should not be limited to a particular type of device, except as specifically claimed.

Referring to FIG. 3, a perspective view of an exemplary GAA transistor 200 is illustrated. The GAA transistor 200 is formed over a substrate 202. The substrate 202 may contains a semiconductor material, such as bulk silicon (Si).

The GAA transistor 200 also includes one or more nanostructures 204 (dash lines) extending in the Y-direction and vertically stacked (or arranged) in the Z-direction. More specifically, the nanostructures 204 are spaced apart from each other in the Z-direction. In some embodiments, the nanostructures 204 may also be referred to as channels, channel layers, nanosheets, or nanowires.

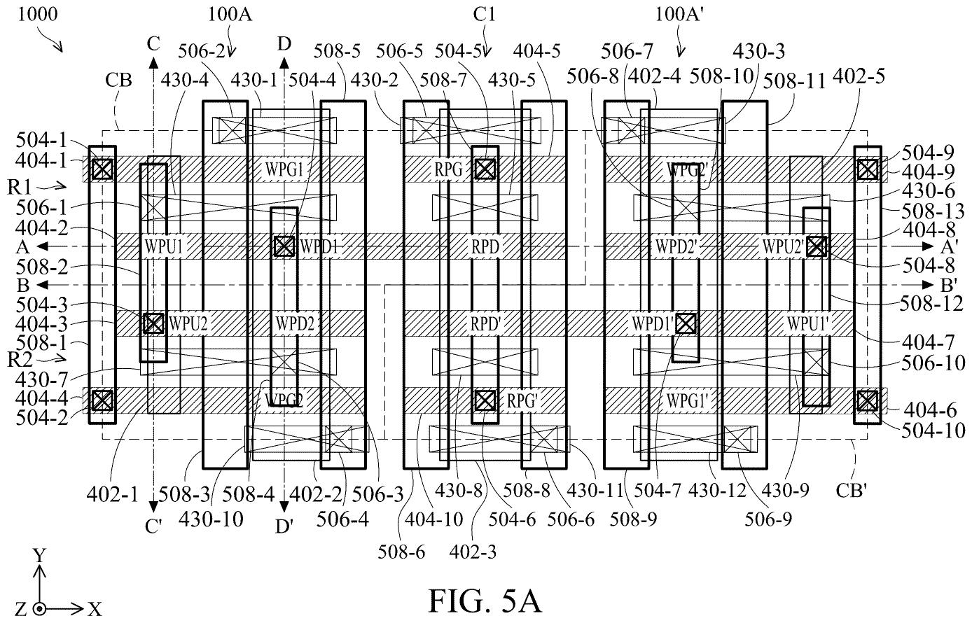

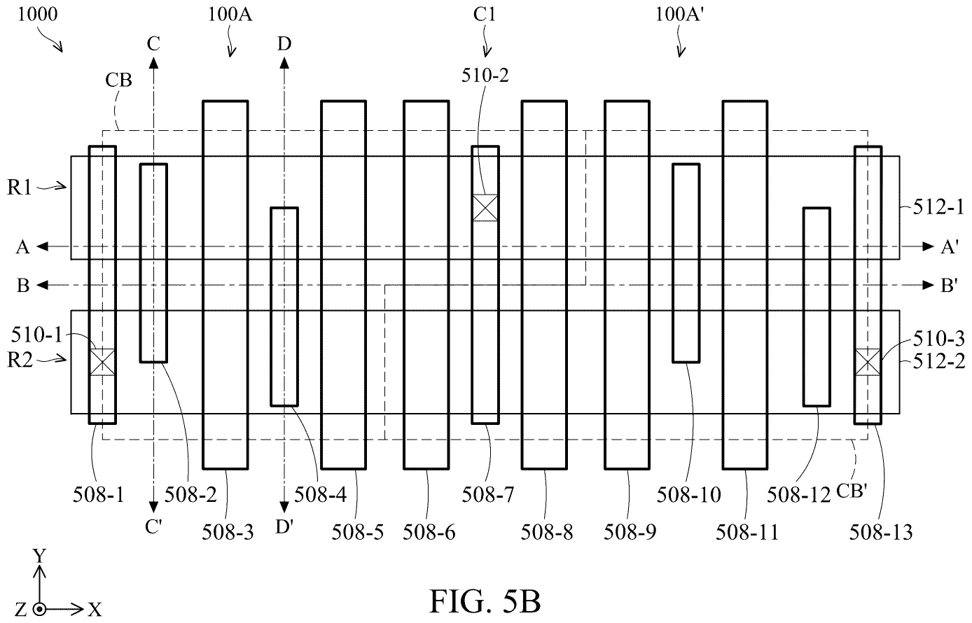

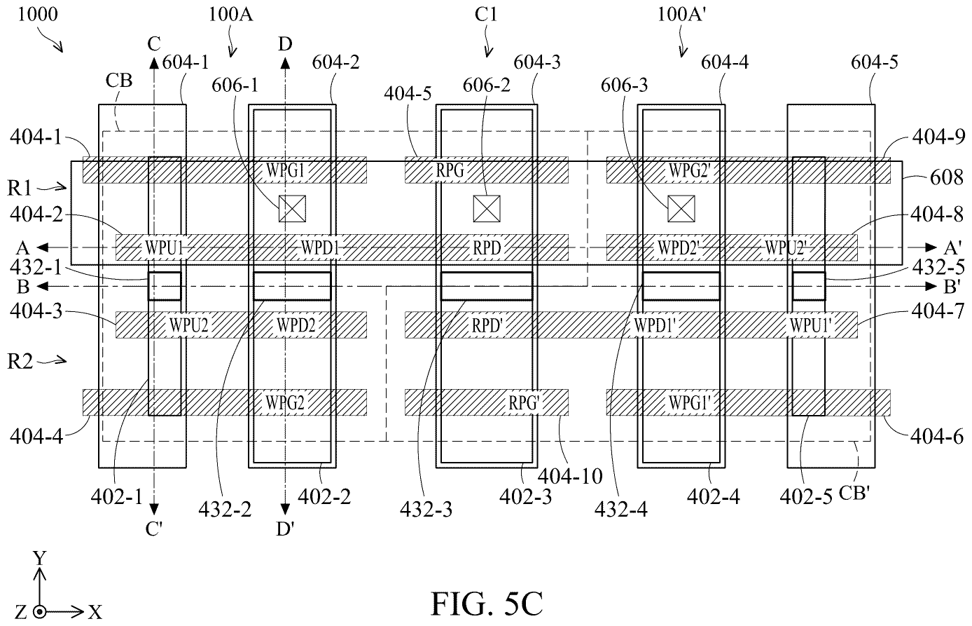

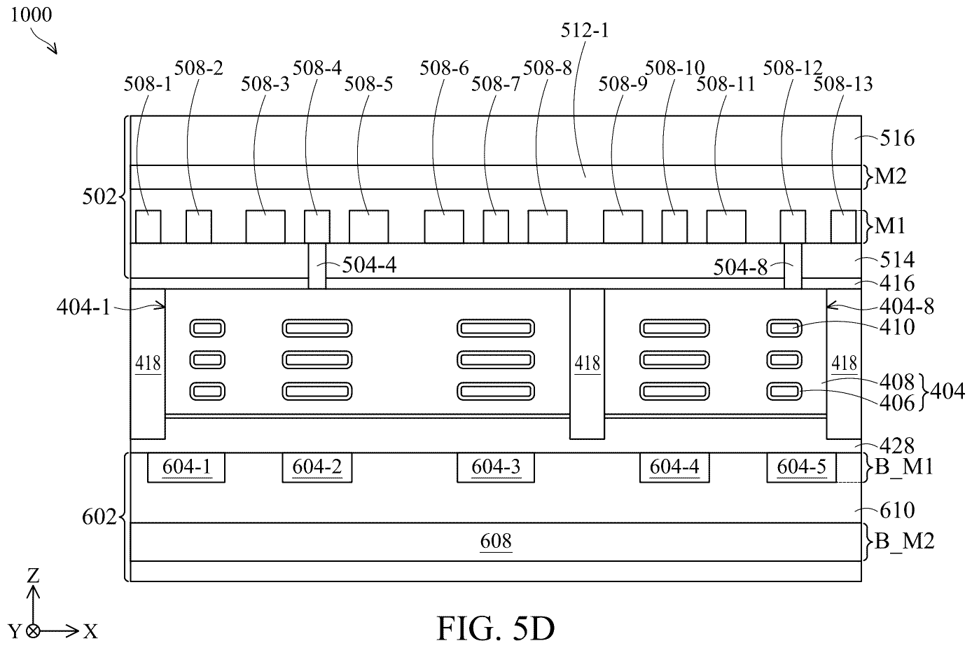

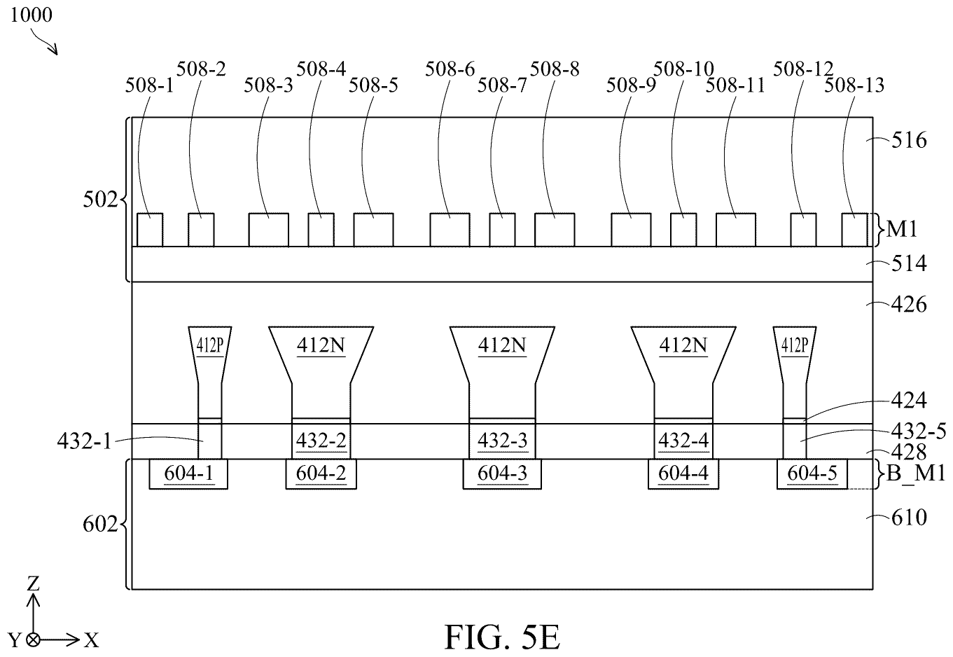

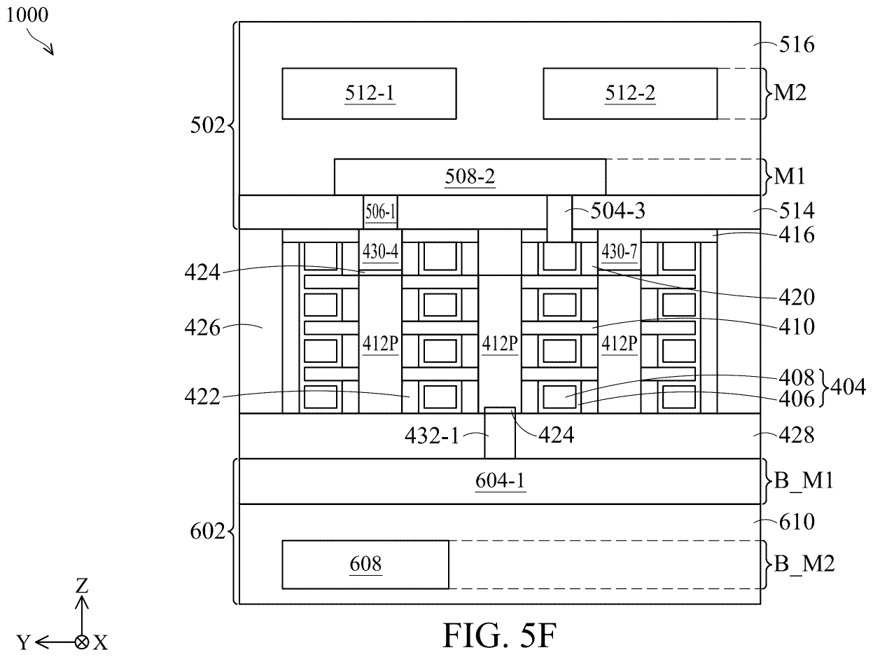

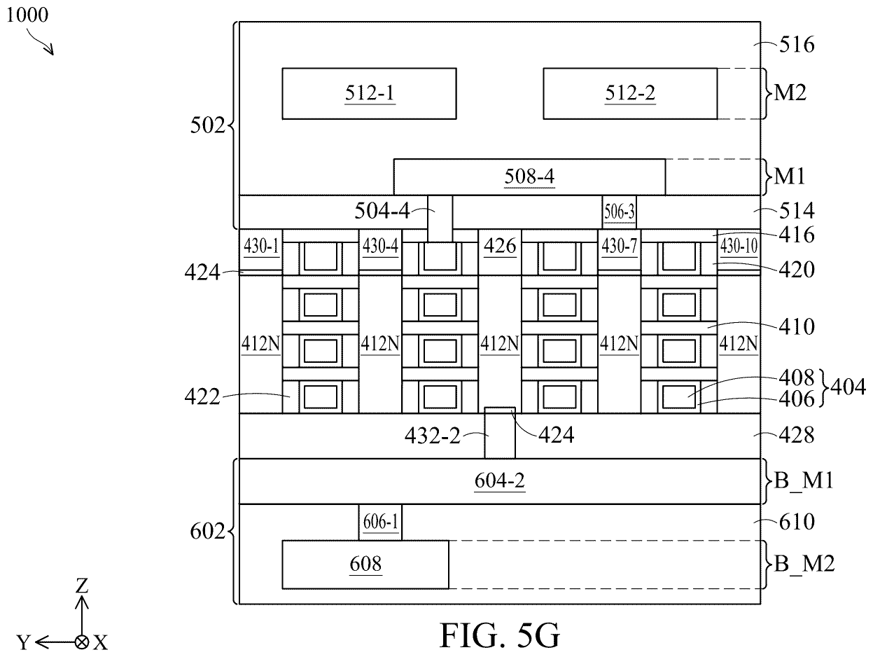

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 3, may refer to FIGS. 5E, 5F, and 5H). As shown in FIG. 3, gate spacers 212 are on sidewalls of the gate structure 206 and over the nanostructures 204 (not shown in FIG. 3, may refer to FIG. 5H). A gate top dielectric layer 214 is over the gate dielectric layer 208, the gate electrode 210, and the nanostructures 204. The gate top dielectric layer 214 is used for contact etch protection layer.

The GAA transistor 200 further includes source/drain features 216. As shown in FIG. 3, two source/drain features 216 are on opposite sides of the gate structure 206. The nanostructures 204 (dash lines) extends in the Y-direction to connect one source/drain feature 216 to the other source/drain feature 216. The source/drain features 216 may also be referred to as source/drain, or source/drain regions. In some embodiments, source/drain feature(s) may refer to a source or a drain, individually or collectively dependent upon the context.

Isolation feature 218 is over the substrate 202 and under the gate dielectric layer 208, the gate electrode 210, and the gate spacers 212. The isolation feature 218 is used for isolating the GAA transistor 200 from other devices. In some embodiments, the isolation feature 218 may include different structures, such as shallow trench isolation (STI) structure, deep trench isolation (DTI) structure. Therefore, the isolation feature 218 is also referred as to as a STI feature or DTI feature.

Generally, interconnection of devices and circuit cells are disposed over or at front-side of transistors to form desired circuit routing. As transistors and circuit cells continue to be scaled down, space for interconnection routing is also decreased. In order to achieve desired circuit routing, metal conductor width and conductor-to-conductor space are decreased, thereby increasing resistance and parasitic capacitance to impact performance of devices and circuit cells. In some embodiments of present disclosure, a part of interconnection of devices and circuit cells is disposed under or at back-side of transistors to improve upon the above issue.

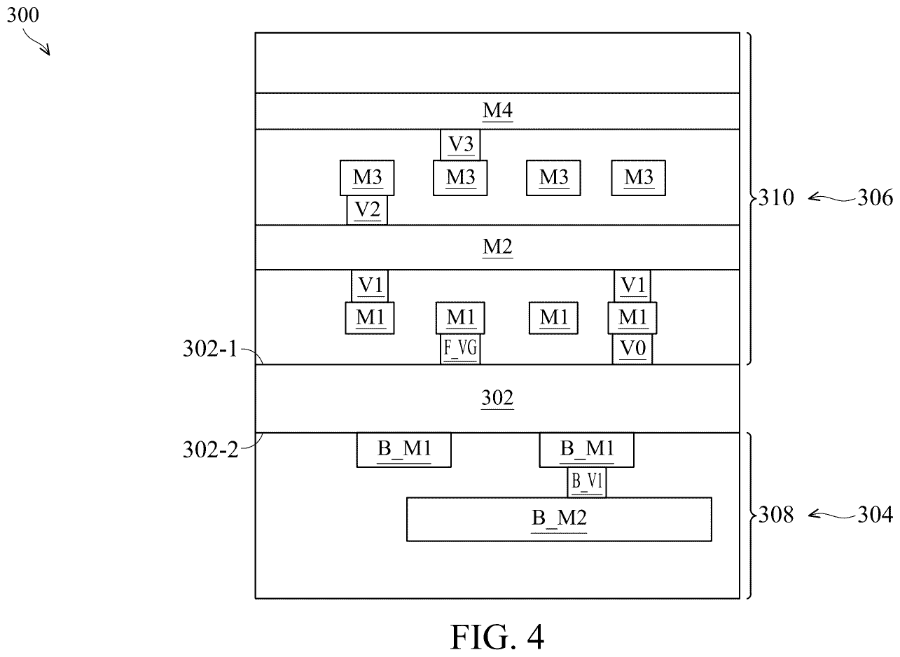

FIG. 4 shows a cross-sectional view of a semiconductor device 300 for illustrating a front-side interconnection structure and a back-side interconnection structure, in accordance with some embodiments of the present disclosure. The semiconductor device 300 has device region 302 (also referred to as a device layer), a back-side interconnection structure 304, and a front-side interconnection structure 306. The device region 302 is the region where the transistors and main features are located, such as gate, channel, source/drain, contact features, and the transistors (e.g., the transistors of the SRAM cell 100 discussed above) of the circuit cells discussed above. The device region 302 has a front side 302-1 and a back side 302-2. The back-side interconnection structure 304 is under the device region 302 or at the back side 302-2 of the device region 302, and the front-side interconnection structure 306 is over the device region 302 or at the front side 302-1 of the device region 302.

As shown in FIG. 4, the back-side interconnection structure 304 includes an inter-metal dielectric (IMD) 308, a metal layer B_M1, and a metal layer B_M2 under the metal layer M1. Each of the metal layers B_M1 and B_M6 includes metal conductors. The back-side interconnection structure 304 further includes vias B_V1 for connecting the metal conductor in the underlying metal layer to the metal conductor in the overlying metal layer. The front-side interconnection structure 306 includes an inter-metal dielectric (IMD) layer 310, a metal layer M1, a metal layer M2 over the metal layer M1, a metal layer M3 over the metal layer M2, and a metal layer M4 over the metal layer M3. Each of the metal layers M1, M2, M3, and M4 includes metal conductors. The front-side interconnection structure 306 further includes vias F_VG, V0, V1, V2, and V3 for connecting the metal conductor in the underlying metal layer to the metal conductor in the overlying metal layer.

The vias and metal conductors in the IMD layers 308 and 310 electrically couple various transistors and/or components (for example, gate, source/drain features, resistors, capacitors, and/or inductors) in the device region 302, such that the various devices and/or components can operate as specified by the design requirements of circuit cells (e.g., logic cells and memory cells). It should be noted that there may be more vias and metal conductors in the IMD layers 308 and 310 for connections. The IMD layers 308 and 310 may be multilayer structure, such as one or more dielectric layers.

Since the back-side interconnection structure 304 is at the back-side 302-2 of the device region 302, the IMD layer 308, the vias B_V1, and the metal conductors in the metal layers B_M1 and B_M2 may also be referred to as the back-side IMD layer, the back-side vias, and the back-side metal conductors, respectively. Since the front-side interconnection structure 306 is at the front-side 302-1 of the device region 302, the IMD layer 310, the vias F_VG, V0, V1, V2, and V3, and the metal conductors in the metal layers M1, M2, M3, and M4 may also be referred to as the front-side IMD layer, the front-side vias, and the front-side metal conductors, respectively. In some embodiments, the vias F_VG are connected to the gate structures (gate electrodes) of the transistors. Therefore, the vias F_VG connected to the gate structures are also referred to as the gate vias, or referred to as the front-side gate vias.

In some embodiments, the vias and metal conductors in the IMD layers 308 and 310 are used for the connections of the features of the transistor. In other embodiments, the vias and metal conductors are connected to voltage sources (the supply voltage VDD or the reference voltage VSS discussed above) to provide voltage to the transistors in the device region 302. Therefore, the metal conductors (e.g., the metal conductors B_M1, B_M2) connected to the voltage sources may be also referred to as the voltage metal conductors, the voltage lines, or voltage conductors.

For the operation speed of the read-port (e.g., the read-port PG of the SRAM cell 100) of the two-port SRAM cell is major dominated by transistor on-current and capacitance, in the present disclosure, the metal conductors serving as the read bit-lines, the write bit-lines, the write bit-line-bars, the VDD lines, and the VSS lines are designed to be located in the lowest metal layer (i.e., the metal layer M1 in the front-side interconnection structure and the metal layer B_M1 in the back-side interconnection structure) to have lower capacitance (save metal landing pad capacitance if located at higher metal layers). Furthermore, since the read word-lines and the write word-lines are more care about resistance, the metal conductors serving as the read word-lines and the write word-lines are designed to be located in the higher

Therefore, in some embodiments, the metal conductors serving as read bit-lines, write bit-lines, and write bit-line-bars are designed to be located in the metal layer M1; the metal conductors serving as write word-lines and read word-lines are designed to be located in the metal layer M2; and the metal conductors serving as VDD lines and VSS lines are designed to be located in the metal layer B_M1.

FIGS. 5A to 5C illustrate top views (or layouts) of features in a device region, a front-side interconnection structure, and a back-side interconnection structure of two adjacent SRAM cells 100A and 100A′ in a portion of an array 1000 that can be one embodiment of the SRAM cells 100 in adjacent two rows implemented in the memory region 20, in accordance with some embodiments of the present disclosure. FIG. 5A illustrates the features in the device region (including transistors) and the front-side interconnection structure including the metal conductors in the first metal layer (M1), and vias (V0, F_VG) vertically between the features and the first metal layer (M1). FIG. 5B illustrates the front-side interconnection structure including metal conductors in the first metal layer (M1) and the second metal layer (M2), and vias (V1) vertically between the first metal layer (M1) and the second metal layer (M2). FIG. 5C illustrates the back-side interconnection structure including the metal conductors in the second metal layer (B_M1) and the third metal layer (B_M2), and vias (B_V1) vertically between the second metal layer (B_M1) and the third metal layer (B_M2).

FIG. 5D is an X-Z cross-sectional view of the array 1000 along a line A-A′ in FIGS. 5A to 5C, in accordance with some embodiments of the present disclosure. FIG. 5E is an X-Z cross-sectional view of the array 1000 along a line B-B′ in FIGS. 5A to 5C, in accordance with some embodiments of the present disclosure. FIG. 5F is a Y-Z cross-sectional view of the array 1000 along a line C-C′ in FIGS. 5A to 5C, in accordance with some embodiments of the present disclosure. FIG. 5G is a Y-Z cross-sectional view of the array 1000 along a line D-D′ in FIGS. 5A to 5C, in accordance with some embodiments of the present disclosure.

As shown in FIGS. 5A to 5C, the array 1000 shows a row R1 having the SRAM cell 100A which is abutted and adjacent to the SRAM cell 100A′ in a row R2. More specifically, the adjacent two SRAM cells 100A and 100A′ are respectively in the adjacent two rows R1 and R2, and are together in a column Cl. In other words, the SRAM cell 100A′ is abutted and adjacent to the SRAM cell 100A in the X-direction, as shown in FIGS. 5A to 5C.

The SRAM cells 100A and 100A′ each respectively has a cell boundary CB and a cell boundary CB′. Each of the cell boundaries CB and CB′ has a non-rectangular shape (indicated by the dotted rectangular box). More specifically, each of the cell boundaries CB and CB′ is L-shaped in a top view (or an X-Y plane view), as shown in FIG. 5A to 5C. Therefore, in some embodiments, the cell boundaries CB and CB′ may be referred to as non-rectangular cell boundaries or L-shaped cell boundaries. The SRAM cells 100A and 100A′ are abutted together in the X-direction, such that the cell boundary CB abuts the cell boundary CB′ in the X-direction to form a rectangular shape, as shown in FIGS. 5A to 5C. Furthermore, the cell boundaries CB and CB′ are rotational symmetry by a rotation of 180 degrees.

The array 1000 includes active areas, such as active areas 402-1 to 402-5, (may be collectively referred to as the active areas 402) that extend lengthwise in the Y-direction and are arranged in the X-direction. The active areas 402-1 and 402-2 are used for the SRAM cell 100A; the active areas 402-4 and 402-5 are used for the SRAM cell 100A′; and the active area 402-3 is shared by the SRAM cells 100A and 100A′. Each of active areas 402 includes channel regions, source regions, and drain regions (where source regions and drain regions are collectively referred to as source/drain regions herein) of transistors.

The array 1000 further includes gate structures, such as gate structures 404-1 to 404-10 (may be collectively referred to as the gate structures 404) that extend lengthwise in the X-direction. The X-direction and the Y-direction are perpendicular. The gate structures 404-1 to 404-10 are disposed over the channel regions of the respective active areas 402-1 to 402-5 (i.e., (vertically stacked) nanostructures 410) and disposed between respective source/drain regions of the active areas 402-1 to 402-5 (i.e., source/drain features 412N and 412P). In some embodiments, the gate structures 404-1 to 404-10 wrap and/or surround suspended, vertically stacked nanostructures 410 in the channel regions of the active areas 402-1 to 402-5, respectively (as shown in FIGS. 5D, 5F, and 5G).

In the SRAM cell 100A, the gate structure 404-1 extends across the active area 402-2 in the top view and engages the active area 402-2 to form the WPG transistor WPG1; the gate structure 404-2 extends across the active areas 402-1 to 402-3 in the top view and engages the active area 402-1 to 402-3 to respectively form the WPU transistor WPU1, the WPD transistor WPD1, and the RPD transistor RPD; the gate structure 404-3 extends across the active areas 402-1 and 402-2 in the top view and engages the active areas 402-1 and 402-2 to respectively form the WPU transistor WPU2 and the WPD transistor WPD2; the gate structure 404-4 extends across the active area 402-2 in the top view and engages the active area 402-2 to form the WPG transistor WPG2; and the gate structure 404-5 extends across the active area 402-3 in the top view and engages the active area 402-3 to form the RPG transistor RPG.

In the SRAM cell 100A′, the gate structure 404-6 extends across the active area 402-4 in the top view and engages the active area 402-4 to form the WPG transistor WPG1′; the gate structure 404-7 extends across the active areas 402-3 to 402-5 in the top view and engages the active area 402-3 to 402-5 to respectively form the R PD transistor RPD′, the WPD transistor WPD1′, and the WPU transistor WPU1′; the gate structure 404-8 extends across the active areas 402-5 and 402-4 in the top view and engages the active areas 402-5 and 402-4 to respectively form the WPU transistor WPU2′ and the WPD transistor WPD2′; the gate structure 404-9 extends across the active area 402-4 in the top view and engages the active area 402-4 to form the WPG transistor WPG2′; and the gate structure 404-10 extends across the active area 402-3 in the top view and engages the active area 402-3 to form the RPG transistor RPG′.

As shown in FIGS. 5A and 5C, the WPU transistor WPU1 and the WPU transistor WPU2 are arranged in the Y-direction and share the active area 402-1; the WPG transistor WPG1, the WPD transistor WPD1, the WPD transistor WPD2, and the WPG transistor WPG2 are arranged in the Y-direction and share the active area 402-2; the RPG transistor RPG, the RPD transistor RPD, the RPD transistor RPD′, and the RPG transistor RPG′ are arranged in the Y-direction and share the active area 402-3; the WPG transistor WPG1′, the WPD transistor WPD1′, the WPD transistor WPD2′, and the WPG transistor WPG2′ are arranged in the Y-direction and share the active area 402-4; and the WPU transistor WPU1′ and the WPU transistor WPU2′ are arranged in the Y-direction and share the active area 402-5.

Each of the transistors in the SRAM cell 100A (e.g., the WPG transistors WPG1 and WPG2, the WPD transistors WPD1 and WPD2, the WPU transistors WPU1 and WPU2, the RPG transistor RPG, and the RPD transistor RPD) and the transistors in the SRAM cell 100A′ (e.g., the WPG transistors WPG1′ and WPG2′, the WPD transistors WPD1′ and WPD2′, the WPU transistors WPU1′ and WPU2′, the RPG transistor RPG′, and the RPD transistor RPD′) includes nanostructures 410 similar to the nanostructures 204 discussed above. As shown in FIGS. 5D, 5F, and 5G, the nanostructures 410 are suspended. In some embodiments, three nanostructures 410 are vertically stacked (or vertically arranged) from each other in the Z-direction for one transistor. However, there may be another appropriate number of nanostructures in one transistor. For example, there may be from 2 to 6 nanostructures 410 in one transistor.

The nanostructures 410 further extend lengthwise in the Y-direction (FIG. 5D) and widthwise in the X-direction (FIGS. 5F and 5G). In some embodiments, a width of the nanostructures 410 in the active area 402-3 in the X-direction is greater than a width of the nanostructures 410 in the active areas 402-2 and 402-4 in the X-direction, and the width of the nanostructures 410 in the active areas 402-2 and 402-4 in the X-direction is greater than a width of the nanostructures 410 in the active areas 402-1 and 402-5 in the X-direction, as shown in FIGS. 5A, 5C, and 5D. As shown in FIG. 5D, in each of the transistors in the SRAM cell 100A and 100A′, three nanostructures 410 are spaced apart from each other in the Z-direction.

The nanostructures 410 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 410 include silicon for n-type transistors, such as the WPD transistors WPD1, WPD2, WPD1′, and WPD2′, the WPG transistors WPG1, WPG2, WPG1′, and WPG2′, the RPD transistors RPD and RPD′, and the RPG transistors RPG and RPG′. In other embodiments, the nanostructures 410 include silicon germanium for p-type transistors, such as the WPU transistors WPU1, WPU2, WPU1′, and WPU2′. In some embodiments, the nanostructures 410 are all made of silicon, and the type of the transistors depend on work function metal layer wrapping around the nanostructures 410. In some embodiments, the nanostructures 410 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

Each of the gate structures 404-1 to 404-10 has a gate dielectric layer 406 and a gate electrode layer 408. The gate dielectric layers 406 wrap around each of the nanostructures 410, and the gate electrodes layer 408 wrap around the gate dielectric layer 406 and the nanostructures 410. In some embodiments, the gate structures 404 each further includes an interfacial layer (such as having silicon dioxide, silicon oxynitride, or other suitable materials) between the gate dielectric layer 406 and the nanostructures 410.

The gate dielectric layers 406 may include oxide with nitrogen doped dielectric material (initial layer) combined with metal content high-K dielectric material (K value (dielectric constant)>13). For example, gate dielectric layers 406 may include hafnium oxide (HfO₂), which has a dielectric constant in a range from about 18 to about 40. Alternatively, the gate dielectric layers 406 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 406 may be formed by chemical oxidation, thermal oxidation, ALD, CVD, and/or other suitable methods.

The gate electrode layer 408 is formed to wrap around the gate dielectric layer 406 and the center portions of the nanostructures 410, as shown in FIGS. 5F and 5G. In some embodiments, the gate electrode layer 408 may include an n-type work function metal layer for n-type transistor (such as the WPD transistors WPD1, WPD2, WPD1′, and WPD2′, the WPG transistors WPG1, WPG2, WPG1′, and WPG2′, the RPD transistors RPD and RPD′, and the RPG transistors RPG and RPG′) or a p-type work function metal layer for p-type transistor (such as the WPU transistors WPU1, WPU2, WPU1′, and WPU2′).

More specifically, each of the gate electrode layers 408 may have n-type work function metal layers between the source/drain features 412N with an n-type dopant for an n-type transistor (such as the WPD transistors WPD1, WPD2, WPD1′, and WPD2′, the WPG transistors WPG1, WPG2, WPG1′, and WPG2′, the RPD transistors RPD and RPD′, and the RPG transistors RPG and RPG′) and p-type work function metal layers between the source/drain features 412P with a p-type dopant for a p-type transistor (such as the WPU transistors WPU1, WPU2, WPU1′, and WPU2′), in accordance with some embodiments of the present disclosure.

In an embodiment, the n-type work function metal layer is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

In an embodiment, the p-type work function metal layer is a material such as TiN, TaN, Ru, Mo, Al, WN, ZrSi₂, MoSi₂, TaSi₂, NiSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, other suitable p-type work function materials, combinations of these, or the like. Additionally, the p-type work function metal layer may be deposited using a deposition process such as ALD, CVD, or the like, although any suitable deposition process may be used.

In some embodiments, the gate electrode layer 408 may include a single layer or alternatively a multi-layer structure. In some embodiments, the gate electrode layer 408 may further include a capping layer, a barrier layer, and a fill material (not shown). The capping layer may be formed adjacent to the gate dielectric layers 406 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent to the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The SRAM cells 100A and 100A′ further include gate spacers 420 are on sidewalls of the gate structures 404 and over the nanostructures 410, as shown in FIGS. 5F and 5G. More specifically, the gate spacers 420 are over the nanostructures 410 and on top sidewalls of the gate structures 404, and thus are also referred to as gate top spacers or top spacers. The gate spacers 420 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 420 may include a single layer or a multi-layer structure.

As shown in FIGS. 5F and 5G, the SRAM cells 100A and 100A′ further include inner spacers 422 on the sidewalls of the gate structures 404 and below the topmost nanostructures 410 and the gate spacers 420. Furthermore, the inner spacers 422 are laterally between the source/drain features 412N (or 412P) and the gate structures 404. The inner spacers 422 are also vertically between adjacent nanostructures 410. The inner spacers 422 may include a dielectric material having higher K value (dielectric constant) than the gate spacers 420 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the thickness of the gate spacers 420 in the Y-direction and the thickness of the inner spacers 422 in the Y-direction are the same. In other embodiments, the thickness of the gate spacers 420 in the Y-direction is less than the thickness of the inner spacers 422 in the Y-direction due to the gate spacers 420 are trimmed during processes for forming source/drain contacts.

Referring to FIGS. 5F and 5G, the SRAM cells 100A and 100A′ further include source/drain features 412N and source/drain features 412P in the source/drain regions of the active areas 402. The source/drain features 412N are disposed on opposite sides of the respective gate structure 404 and connected by the nanostructures 410 to form n-type transistor (e.g., the WPD transistors WPD1, WPD2, WPD1′, and WPD2′, the WPG transistors WPG1, WPG2, WPG1′, and WPG2′, the RPD transistors RPD and RPD′, and the RPG transistors RPG and RPG′). Similarly, the source/drain features 412P are disposed on opposite sides of the respective gate structure 404 and connected by the nanostructures 410 to form p-type transistor (e.g., the WPU transistors WPU1, WPU2, WPU1′, and WPU2′). In some aspects, the source/drain features 412N/412P are disposed on opposite sides of the respective nanostructures 410. More specifically, the source/drain features 412N/412P are attached and electrically connected to the nanostructures 410 in the Y-direction, as shown in FIGS. 5F and 5G. Furthermore, every two adjacent transistors in the Y direction share one source/drain feature 412N/412P, as shown in FIGS. 5A, 5F, and 5G. In some embodiments, each of the source/drain features 412N/412P has a top portion with an inverted trapezoid shape and a bottom portion with a rectangular shape in the X-Z cross-sectional view, as shown in FIG. 5E. Therefore, a dimension of a top surface of each of the source/drain features 412N/412P in the X-direction is greater than a dimension of a bottom surface of each of the source/drain features 412N/412P in the X-direction, as shown in FIG. 5E.

The source/drain features 412N and 412P may be formed by using an epitaxial growth process. In some embodiments, the source/drain features 412N may include epitaxially-grown material selected from a group consisting of SiP, SiC, SiPC, SiAs, Si, or a combination thereof. In some embodiments, the epitaxially-grown material of the source/drain features 412N may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 412N for n-type transistors may be respectively referred to as n-type features and n-type source/drain features.

In some embodiments, the source/drain features 412P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 412P may be doped with p-type dopants (such as boron, indium, other p-type dopant, or combinations thereof) having a doping concentration in a range from about 1×10¹⁹/cm³ to 6×10²⁰/cm³. In some embodiments, the source/drain features 412P for p-type transistors may be respectively referred to as p-type source/drain features.

Referring to FIG. 5D, the SRAM cells 100A and 100A′ further include gate end dielectric structures 418 at ends of the gate structures 404. The gate end dielectric structures 418 are used for separating the gate structures 404 aligned in the X-direction. For example, the gate end dielectrics 418 separate the gate structures 404-2 and 404-8, as shown in FIG. 5D. The gate end dielectric structures 418 are also used for separating the abutted SRAM cells 100A and 100A′ from other device (e.g., SRAM cells or logic cells) in the X-direction. Furthermore, as shown in FIG. 5D, the gate end dielectric structure 418-3 are in contact with the gate structures 404 in the X-direction. As shown in FIGS. 5D, the gate end dielectric structures 418 further extend into a dielectric layer 428 in the Z-direction. In some embodiments, bottom surfaces of the gate end dielectric structures 418 are lower than bottom surfaces of the gate structures 404, as shown in FIG. 5D.

The material of the gate end dielectric structures 418 can be single dielectric layer or multiple layers and selected from a group consisting of Si₃N₄, nitride based dielectric layer, SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or combinations thereof.

The SRAM cells 100A and 100A′ further include gate top dielectric layers 416 are over the gate dielectric layers 406, the gate electrode layers 408, the nanostructures 410, and the gate spacers 420. The gate top dielectric layers 416 are similar to the gate top dielectric layer 214 discussed above. The gate top dielectric layer 416 is used for contact etch protection layer. The material of gate top dielectric layer 416 is selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable material.

Referring to FIGS. 5A to 5G, the SRAM cells 100A and 100A′ further include source/drain contacts 430 (including source/drain contacts 430-1 to 430-12) in an inter-layer dielectric (ILD) layer 426 and source/drain contacts 432 (including source/drain contacts 432-1 to 432-5) in a dielectric layer 428. As shown in FIGS. 5A and 5C, the source/drain contacts 430 and 432 extend lengthwise in the X-direction. The source/drain contacts 430 are self-aligned source/drain contacts. This means that the source/drain contacts 430 are formed by using the gate spacers 420 as a mask. Therefore, the source/drain contacts 430 are in direct contact with the gate spacers 420, as shown in FIGS. 5F and 5G. In some embodiments, the gate spacers 420 are trimmed due to the gate spacers 420 serving as the mask for forming the source/drain contacts 430. Therefore, the thickness of the gate spacers 420 in the Y-direction is less than the thickness of the inner spacers 422 in the Y-direction, as discussed above.

In the top view, as shown in FIG. 5A, the source/drain contacts 430-1, 430-2, 430-10 lengthwise overlap the cell boundary CB, the source/drain contacts 430-3, 430-11, 430-12 lengthwise overlap the cell boundary CB′, and the source/drain contact 432-3 lengthwise overlap the cell boundaries CB and CB′.

In the top view, the source/drain contact 430-1 is adjacent to the gate structure 404-1 (or is adjacent to the WPG transistor WPG1) in the Y-direction; the source/drain contact 430-2 is adjacent to the gate structure 404-5 (or is adjacent to the RPG transistor RPG) in the Y-direction; the source/drain contact 430-3 is adjacent to the gate structure 404-9 (or is adjacent to the WPG transistor WPG2′) in the Y-direction; the source/drain contact 430-4 is between the gate structures 404-1 and 404-2 (or between the WPG transistor WPG1 and the WPD transistor WPD1) in the Y-direction; the source/drain contact 430-5 is between the gate structures 404-5 and 404-2 (or between the RPG transistor RPG and the RPD transistor RPD) in the Y-direction; the source/drain contact 430-6 is between the gate structures 404-9 and 404-8 (or between the WPG transistor WPG2′ and the WPD transistor WPD2′) in the Y-direction; the source/drain contact 430-7 is between the gate structures 404-3 and 404-4 (or between the WPG transistor WPG2 and the WPD transistor WPD2) in the Y-direction; the source/drain contact 430-8 is between the gate structures 404-7 and 404-10 (or between the RPG transistor RPG′ and the RPD transistor RPD′) in the Y-direction; the source/drain contact 430-9 is between the gate structures 404-6 and 404-7 (or between the WPG transistor WPG1′ and the WPD transistor WPD1′) in the Y-direction; the source/drain contact 430-10 is adjacent to the gate structure 404-4 (or is adjacent to the WPG transistor WPG2) in the Y-direction; the source/drain contact 430-11 is adjacent to the gate structure 404-10 (or is adjacent to the RPG transistor RPG′) in the Y-direction; and the source/drain contact 430-12 is adjacent to the gate structure 404-6 (or is adjacent to the WPG transistor WPG1′) in the Y-direction.

In the top view, as shown in FIG. 5C, the source/drain contact 432-1 is between the gate structures 404-2 and 404-3 (or between the WPU transistors WPU1 and WPU2) in the Y-direction; the source/drain contact 432-2 is between the gate structures 404-2 and 404-3 (or between the WPD transistors WPD1 and WPD2) in the Y-direction; the source/drain contact 432-3 is between the gate structures 404-2 and 404-4 (or between the RPD transistors RPD and RPD′) in the Y-direction; the source/drain contact 432-4 is between the gate structures 404-7 and 404-8 (or between the WPD transistors WPD1′ and WPD2′) in the Y-direction; and the source/drain contact 432-5 is between the gate structures 404-7 and 404-8 (or between the WPU transistors WPU1′ and WPU2′) in the Y-direction.

Furthermore, each of the source/drain contacts 430 is over and electrically connected to the respective source/drain features 412N/412P and each of the source/drain contacts 432 is under electrically connected to the respective source/drain features 412N/412P. Specifically, as shown in FIGS. 5A, 5F, and 5G, the source/drain contact 430-1 is over and electrically connected to the source/drain feature 412N of the WPG transistor WPG1; the source/drain contact 430-2 is over and electrically connected to the source/drain feature 412N of the RPG transistor RPG; the source/drain contact 430-3 is over and electrically connected to the source/drain feature 412N of the WPG transistor WPG2′; the source/drain contact 430-4 is over and electrically connected to the source/drain feature 412N shared by the WPG transistor WPG1 and the WPD transistor WPD1 (also referred to as common source/drain or common drain) and the source/drain feature 412P of the WPU transistor WPU1, which corresponds to the data node ND shown in FIG. 2; the source/drain contact 430-5 is over and electrically connected to the source/drain feature 412N shared by the RPG transistor RPG and the RPD transistor RPD; the source/drain contact 430-6 is over and electrically connected to the source/drain feature 412N shared by the WPG transistor WPG2′ and the WPD transistor WPD2′ (also referred to as common source/drain or common drain) and the source/drain feature 412P of the WPU transistor WPU2′, which corresponds to the data node NDB shown in FIG. 2; the source/drain contact 430-7 is over and electrically connected to the source/drain feature 412N shared by the WPG transistor WPG2 and the WPD transistor WPD2 (also referred to as common source/drain or common drain) and the source/drain feature 412P of the WPU transistor WPU2, which corresponds to the data node NDB shown in FIG. 2; the source/drain contact 430-8 is over and electrically connected to the source/drain feature 412N shared by the RPG transistor RPG′ and the RPD transistor RPD′; the source/drain contact 430-9 is over and electrically connected to the source/drain feature 412N shared by the WPG transistor WPG1′ and the WPD transistor WPD1′ (also referred to as common source/drain or common drain) and the source/drain feature 412P of the WPU transistor WPU1′, which corresponds to the data node ND shown in FIG. 2; the source/drain contact 430-10 is over and electrically connected to the source/drain feature 412N of the WPG transistor WPG2; the source/drain contact 430-11 is over and electrically connected to the source/drain feature 412N of the RPG transistor RPG′; and the source/drain contact 430-12 is over and electrically connected to the source/drain feature 412N of the WPG transistor WPG1′.

As shown in FIGS. 5C, 5F, and 5G, the source/drain contact 432-1 is under and electrically connected to the source/drain feature 412P shared by the WPU transistors WPU1 and WPU2; the source/drain contact 432-2 is under and electrically connected to the source/drain feature 412N shared by the WPD transistor WPD1 and WPD2; the source/drain contact 432-3 is under and electrically connected to the source/drain feature 412N shared by the RPD transistors RPD and RPD′; the source/drain contact 432-4 is under and electrically connected to the source/drain feature 412N shared by the WPD transistor WPD1′ and WPD2′; the source/drain contact 432-5 is under and electrically connected to the source/drain feature 412P shared by the WPU transistors WPU1′ and WPU2′.

In some embodiments, the source/drain contacts 430 may be referred to as front-side source/drain contacts due to the source/drain contacts 430 are over the source/drain features 412N/412P. In some embodiments, the source/drain contacts 432 may be referred to as back-side source/drain contacts due to the source/drain contacts 432 are under the source/drain features 412N/412P.

The source/drain contacts 430 and 432 may each include a conductive material such as Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 430 and 432 may each include single conductive material layer or multiple conductive layers.

As shown in FIGS. 5F and 5G, the SRAM cells 100A and 100A′ further include silicide features 424 over or under the source/drain features 412N and 412P. More specifically, the silicide features 424 are formed between the source/drain contacts 430 and the source/drain features 412N/412P and between the source/drain contacts 432 and the source/drain features 412N/412P. The silicide features 424 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

As discussed above, the front-side interconnection structure is over the device region or at the front-side of the device region. As shown in FIGS. 5A to 5G, the array 1000 further include a front-side interconnection structure 502 having gate vias 504 (including gate vias 504-1 to 504-10), vias 506 (including vias 506-1 to 506-10), metal conductors 508 (including metal conductors 508-1 to 508-13), vias 510 (including vias 510-1 to 510-3), metal conductors 512 (including metal conductors 512-1 and 512-2), an ILD layer 514, and an inter-metal dielectric (IMD) layer 516, which are over (or at the front-side of) the transistors in the SRAM cells 100A and 100A′ (e.g., the WPG transistors WPG1, WPG2, WPG1′, and WPG2′, the WPD transistors WPD1, WPD2, WPD1′, and WPD2′, the WPU transistors WPU1, WPU2, WPU1′, and WPU2′, the RPG transistors RPG and RPG′, and the RPD transistors RPD and RPD′).

The gate vias 504 and vias 506 are in the ILD layer 514. The vias 510 and metal conductors 508 and 512 are in the IMD layer 516. The metal conductors 508 and 512 are respectively in the (front-side) metal layers M1 and M2, as discussed above. The metal layer M1 is over the SRAM cells 100A and 100A′ and the metal layer M2 is over the metal layer M1, and thus the metal conductors 508 are over the transistors (e.g., the WPG transistors WPG1, WPG2, WPG1′, and WPG2′, the WPD transistors WPD1, WPD2, WPD1′, and WPD2′, the WPU transistors WPU1, WPU2, WPU1′, and WPU2′, the RPG transistors RPG and RPG′, and the RPD transistors RPD and RPD′) and features (including the source/drain contacts 430, the source/drain features 412N/412P, the nanostructures 410, and gate structures 404) of the SRAM cells 100A and 100A′, and the metal conductors 512 are over the metal conductors 508. As show in FIGS. 5A and 5B, the metal conductors 508 extend lengthwise in the Y-direction, and the metal conductors 512 extend lengthwise in the X-direction.

Each of the gate vias 504 is vertically between and electrically connected to the respective gate structure 404 and the respective metal conductor 508. Each of the vias 506 is vertically between and electrically connected to the respective source/drain contact 430 and the respective metal conductor 508. Each of the vias 510 is vertically between and electrically connected to the respective metal conductor 508 and the respective metal conductor 512. In some embodiments, the gate vias 504, the vias 506 and 510 may have a square shape in the top view. In other embodiments, the gate vias 504, the vias 506 and 510 may have a circular shape in the top view.

The gate vias 504, the vias 506, and the vias 510 may be respectively similar to the via F_VG, the via V0, and the vias V1 discussed above. The gate vias 504, the vias 506, the vias 510, the metal conductors 508 and 512, the ILD layer 514, and the IMD layer 516 may also be referred to as front-side gate vias, front-side vias, front-side metal conductors, front-side ILD layer, and front-side IMD layer, respectively.

As discussed above, connections of the SRAM cells 100A and 100A′ correspond to the circuit of the SRAM cell 100 shown in FIG. 2. In some embodiments, the metal conductors 508-6 and 508-8 respectively serve as the read bit-lines RBL discussed above that electrically connected to the source/drain features of the RPG transistors. More specifically, the metal conductor 508-6 and 508-8 respectively serve as the read bit-lines RBL for the SRAM cells 100A and 100A′.

As shown in FIGS. 5A to 5G, for the SRAM cell 100A, the metal conductor 508-6 is electrically connected to the source/drain feature 412N of the RPG transistor RPG through the via 506-5 and the source/drain contact 430-2.

For the SRAM cell 100A′, the metal conductor 508-8 is electrically connected to the source/drain feature 412N of the RPG transistor RPG′ through the via 506-6 and the source/drain contact 430-11.

As shown in FIG. 5A, in the top view, the via 506-5 overlaps the cell boundary CB, and the via 506-6 overlaps the cell boundary CB′. In some embodiments, the metal conductors 508-6 and 508-8 may be referred to as read bit-line conductor.

In some embodiments, the metal conductors 508-2 and 508-12 serve as data node ND as discussed above, and the metal conductors 508-4 and 508-10 serve as data node NDB as discussed above. In the top view, as shown in FIG. 5A, the metal conductor 508-2 is across the gate structures 404-2 and 404-3 and the source/drain contact 430-4; the metal conductor 508-4 is across the gate structures 404-2 and 404-3 and the source/drain contact 430-7; the metal conductor 508-10 is across the gate structures 404-7 and 404-8 and the source/drain contact 430-6; and the metal conductor 508-12 is across the gate structures 404-7 and 404-8 and the source/drain contact 430-9.

As shown in FIG. 5A, for the SRAM cell 100A, the metal conductor 508-2 is electrically connected to the source/drain contact 430-4 (thus also electrically connected to the source/drain feature 412N shared by the WPG transistor WPG1 and the WPD transistor WPD1 and the source/drain feature 412P of the WPU transistor WPU1) through the via 506-1 and the gate structure 404-3 through the gate via 504-3; the metal conductor 508-4 is electrically connected to the source/drain contact 430-7 (thus also electrically connected to the source/drain feature 412N shared by the WPG transistor WPG2 and the WPD transistor WPD2 and the source/drain feature 412P of the WPU transistor WPU2) through the via 506-3 and the gate structure 404-2 through the gate via 504-4.

For the SRAM cell 100A′, the metal conductor 508-12 is electrically connected to the source/drain contact 430-9 (thus also electrically connected to the source/drain feature 412N shared by the WPG transistor WPG1′ and the WPD transistor WPD1′ and the source/drain feature 412P of the WPU transistor WPU1′) through the via 506-10 and the gate structure 404-8 through the gate via 504-8; the metal conductor 506-10 is electrically connected to the source/drain contact 430-6 (thus also electrically connected to the source/drain feature 412N shared by the WPG transistor WPG2′ and the WPD transistor WPD2′ and the source/drain feature 412P of the WPU transistor WPU2′) through the via 506-8 and the gate structure 404-7 through the gate via 504-7.

Since the metal conductor 508-2 is connected to the source/drain contact 430-4 that corresponds to the data node ND, the metal conductor 508-12 is connected to the source/drain contact 430-9 that corresponds to the data node ND, the metal conductor 508-4 is connected to the source/drain contact 430-7 that corresponds to the data node NDB, and the metal conductor 508-10 is connected to the source/drain contact 430-6 that corresponds to the data node NDB, the metal conductors 508-2, 508-12, 508-4, and 508-10 may also be referred to as data node lines or data node conductors.

In some embodiments, the metal conductors 508-3, 508-5, 508-9, and 508-11 respectively serve as the write bit-line WBL, the write bit-line-bar WBLB, the write bit-line WBL, and the write bit-line-bar WBLB discussed above that electrically connected to the source/drain features of the WPG transistors. More specifically, the metal conductor 508-3 and 508-5 respectively serve as the write bit-line WBL and the write bit-line-bar WBLB for the SRAM cell 100A, and the metal conductor 508-11 and 508-9 respectively serve as the write bit-line WBL and the write bit-line-bar WBLB for the SRAM cell 100A′.

As shown in FIGS. 5A to 5G, for the SRAM cell 100A, the metal conductor 508-3 is electrically connected to the source/drain feature 412N of the WPG transistor WPG1 through the via 506-2 and the source/drain contact 430-1; and the metal conductor 508-2 is electrically connected to the source/drain feature 412N of the WPG transistor WPG2 through the via 506-4 and the source/drain contact 430-10.

For the SRAM cell 100A′, the metal conductor 508-11 is electrically connected to the source/drain feature 412N of the WPG transistor WPG1′ through the via 506-9 and the source/drain contact 430-12; and the metal conductor 508-9 is electrically connected to the source/drain feature 412N of the WPG transistor WPG2′ through the via 506-7 and the source/drain contact 430-3.

As shown in FIG. 5A, in the top view, the vias 506-2 and 506-4 overlap the cell boundary CB, and the vias 506-7 and 506-9 overlap the cell boundary CB′. In some embodiments, the metal conductors 508-3 and 508-11 may be referred to as write bit-line conductors, and the metal conductors 508-5 and 508-9 may be referred to as write bit-line-bar conductors.

In some embodiments, the metal conductor 512-1 serves as the read word-line RWL discussed above that controls and electrically connected to the gate structures (more specifically, the gate electrodes) of the RPG transistors. More specifically, the metal conductor 512-1 serves as the read word-line RWL shared by the SRAM cells 100A and 100A′.

As shown in FIGS. 5A to 5G, for the SRAM cells 100A and 100A′, the metal conductor 512-1 is electrically connected to the gate structure 404-5 of the RPG transistor RPG through the via 510-2, the metal conductor 508-7, and the gate via 504-5, and is electrically connected to the gate structure 404-10 of the RPG transistor RPG′ through the via 510-2, the metal conductor 508-7, and the gate via 504-6.

In some embodiments, the metal conductor 512-1 may be referred to as read word-line conductor. In some embodiments, the metal conductor 508-7 may be referred to as read word-line landing pad.

In some embodiments, the metal conductor 512-2 serves as the write word-line WWL discussed above that controls and electrically connected to the gate structures (more specifically, the gate electrodes) of the WPG transistors. More specifically, the metal conductor 512-2 serves as the write word-line WWL shared by the SRAM cells 100A and 100A′.

As shown in FIGS. 5A to 5G, for the SRAM cells 100A and 100A′, the metal conductor 512-2 is electrically connected to the gate structure 404-1 of the WPG transistor WPG1 through the via 510-1, the metal conductor 508-1, and the gate via 504-1, is electrically connected to the gate structure 404-4 of the WPG transistor WPG2 through the via 510-1, the metal conductor 508-1, and the gate via 504-2, is electrically connected to the gate structure 404-6 of the WPG transistor WPG1′ through the via 510-3, the metal conductor 508-13, and the gate via 504-10, and is electrically connected to the gate structure 404-9 of the WPG transistor WPG2′ through the via 510-3, the metal conductor 508-13, and the gate via 504-9.

As shown in FIGS. 5A and 5B, in the top view, the via 510-1, the gate vias 504-1 and 504-2 overlap the cell boundary CB, and the via 510-3, the gate vias 504-9 and 504-10 overlap the cell boundary CB′. Furthermore, in the top view, the metal conductor 508-1 lengthwise overlaps the cell boundary CB, and the metal conductor 508-13 lengthwise overlaps the cell boundary CB′. In some embodiments, the metal conductor 512-2 may be referred to as write word-line conductor. In some embodiments, the metal conductors 508-1 and 508-13 may be referred to as write word-line landing pads.

As discussed above, the back-side interconnection structure is under the device region or at the back-side of the device region. As shown in FIGS. 5A to 5G, the array 1000 further include a back-side interconnection structure 602 having metal conductors 604 (including metal conductors 604-1 to 604-5), vias 606 (including vias 606-1 to 606-3), a metal conductor 608, and an inter-metal dielectric (IMD) layer 610, which are under (or at the back-side of) the transistors in the SRAM cells 100A and 100A′ (e.g., the WPG transistors WPG1, WPG2, WPG1′, and WPG2′, the WPD transistors WPD1, WPD2, WPD1′, and WPD2′, the WPU transistors WPU1, WPU2, WPU1′, and WPU2′, the RPG transistors RPG and RPG′, and the RPD transistors RPD and RPD′).

The vias 606, the metal conductors 604, and the metal conductor 608 are in the IMD layer 610. The metal conductors 604 and 608 are respectively in the (back-side) metal layers B_M1 and B_M2, as discussed above. The metal layer B_M1 is under the SRAM cells 100A and 100A′ and the metal layer B_M2 is under the metal layer B_M1, and thus the metal conductors 604 are under the transistors (e.g., the WPG transistors WPG1, WPG2, WPG1′, and WPG2′, the WPD transistors WPD1, WPD2, WPD1′, and WPD2′, the WPU transistors WPU1, WPU2, WPU1′, and WPU2′, the RPG transistors RPG and RPG′, and the RPD transistors RPD and RPD′) and features (including the source/drain contacts 430, the source/drain features 412N/412P, the nanostructures 410, and gate structures 404) of the SRAM cells 100A and 100A′, and the metal conductor 608 is under the metal conductors 604. As show in FIG. 5C, the metal conductors 604 extend lengthwise in the Y-direction, and the metal conductor 608 extends lengthwise in the X-direction.

Each of the source/drain contact 432 is vertically between and electrically connected to the respective source/drain features 412N/412P and the respective metal conductor 604. Each of the vias 606 is vertically between and electrically connected to the respective metal conductor 604 and the respective metal conductor 608. In some embodiments, the vias 606 may have a square shape in the top view. In other embodiments, the vias 606 may have a circular shape in the top view.

The vias 606 may be respectively similar to the vias B_V1 discussed above. The vias 606, the metal conductors 604 and 608, and the IMD layer 610 may also be referred to as back-side vias, back-side metal conductors, and back-side IMD layer, respectively.

In some embodiments, the metal conductors 604-1 and 604-5 serves as VDD lines that are electrically coupled to a voltage source (not shown) (e.g., the supply voltage VDD discussed above) and electrically connected to the source/drain features of the WPU transistors in the SRAM cells 100A and 100A′.

As shown in FIG. 5C, for the SRAM cell 100A, the metal conductor 604-1 is electrically connected to the source/drain feature 412P shared by the WPU transistors WPU1 and WPU2 through the source/drain contact 432-1.

For the SRAM cell 100A′, the metal conductor 604-5 is electrically connected to the source/drain feature 412P shared by the WPU transistors WPU1′ and WPU2′ through the source/drain contact 432-5.

As shown in FIG. 5C, in the top view, the metal conductor 604-1 lengthwise overlaps the cell boundary CB and the active area 402-1, and the metal conductor 604-5 lengthwise overlaps the cell boundary CB′ and the active area 402-5. In some embodiments, the metal conductors 604-1 and 604-5 may be referred to as the VDD conductors or the VDD lines.

The metal conductors 604-2, 604-3, 604-4, and 608 serve as VSS lines that are coupled together, electrically coupled to a voltage source (not shown) (e.g., the reference voltage VSS discussed above), and electrically connected to the source/drain features of the WPD transistors and the RPD transistors in the SRAM cells 100A and 100A′.

As shown in FIG. 5C, the metal conductor 604-2 is electrically connected to the source/drain feature 412N shared by the WPD transistor WPD1 and WPD2 through the source/drain contact 432-2, the metal conductor 604-3 is electrically connected to the source/drain feature 412N shared by the RPD transistors RPD and RPD′ through the source/drain contact 432-3, and the metal conductor 604-4 is electrically connected to the source/drain feature 412N shared by the WPD transistor WPD1′ and WPD2′ through the source/drain contact 432-4, the metal conductor 608 is electrically connected to the metal conductor 604-2 through the via 606-1, is electrically connected to the metal conductor 604-3 through the via 606-2, and is electrically connected to the metal conductor 604-4 through the via 606-3. As such, the metal conductors 604-2, 604-3, 604-4, and 608 and vias 606-1, 606-2, and 606-3 may construct a power mesh to supply the reference voltage VSS to the WPD transistors and the RPD transistors. The metal conductors 604-2, 604-3, 604-4, and 608 may also be seen to be electrically connected with each other in parallel, such that the total resistance of the metal conductors 604-2, 604-3, 604-4, and 608 are reduced, thereby improving the performance of the array 1000.

As shown in FIG. 5C, in the top view, the metal conductor 604-2 lengthwise overlaps the active area 402-2, the metal conductor 604-3 lengthwise overlaps the active area 402-3, and the metal conductor 604-4 lengthwise overlap the active area 402-4. In some embodiments, the metal conductors 604-2, 604-3, 604-4, and 608 may be referred to as VSS conductors or VSS lines.

The ILD layer 426, the dielectric layer 428, the ILD layer 514, the IMD layer 516, and the IMD layer 610 each may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the gate vias 504, the vias 506, the metal conductors 508, the vias 510, the metal conductors 512, the metal conductors 604, the vias 606, and the metal conductor 608 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

As shown in FIGS. 5A to 5C, the metal conductor 512-2 serving as the write word-line WWL and the metal conductor 512-1 serving as the read word-line RWL are more concerned about the resistance, so that the metal conductors 512-1 and 512-2 may be disposed at the higher metal layer to have more space, thereby it may be designed with wider width to reduce the resistance. In some embodiments, the widths of the metal conductors 512-1 and 512-2 in the Y-direction are greater than the widths of the metal conductors 508 in the X-direction, as shown in FIGS. 5A to 5C.

The metal conductors 508-6 and 508-8 serving as the read bit-lines RBL are more concerned about the capacitance, so that the metal conductors 508-6 and 508-8 are preferred to put in lowest level metallization layer in the front-side interconnection structure (e.g., the metal layer M1 discussed above) for bit-line capacitance reduction.

Furthermore, the metal conductors 508-3, 508-5, 508-9, and 508-11 respectively serving as the write bit-line WBL, the write bit-line-bar WBLB, the write bit-line WBL, and the write bit-line-bar WBLB are also in the lowest level metallization layer in the front-side interconnection structure (e.g., the metal layer M1 discussed above) to have lower capacitance, thereby improving the performance of the semiconductor devices.

The metal conductors 604 serving as the VDD lines and the VSS lines are in the lowest level metallization layer in the back-side interconnection structure (e.g., the metal layer B_M1 discussed above) to have lower capacitance. Furthermore, this is also means that the crowded space at the front-side interconnection structure in existing technologies are relieved to reduce the routing complexity of the SRAM cells. The metal conductors 604 serving as the VDD lines and the VSS lines may also be designed with wider width to reduce the resistance due to the broad space at the back-side interconnection structure. As shown in FIGS. 5A to 5C, the widths of the metal conductors 604 in the X-direction are greater than the widths of the metal conductors 508 in the X-direction.

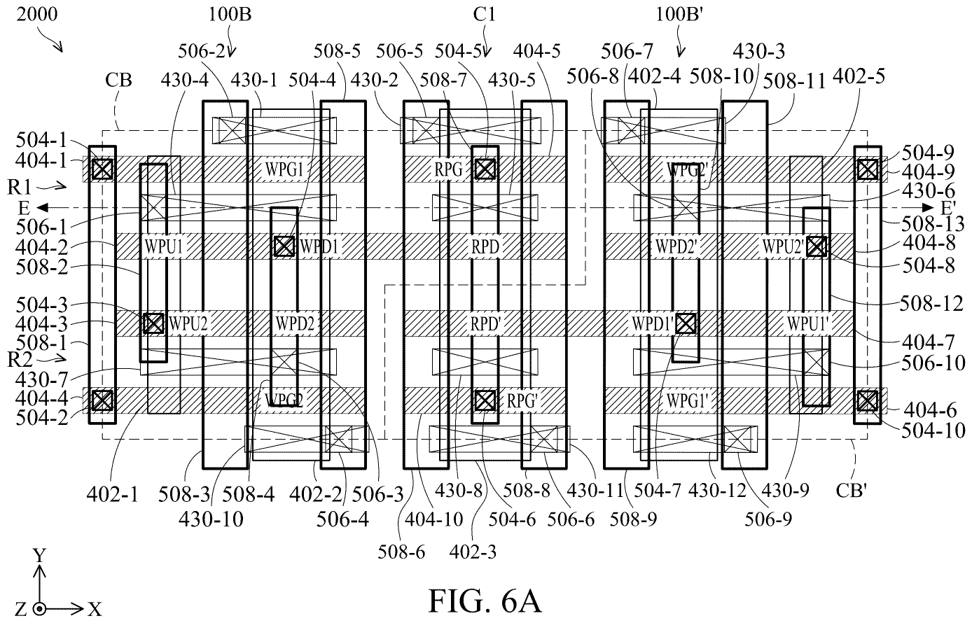

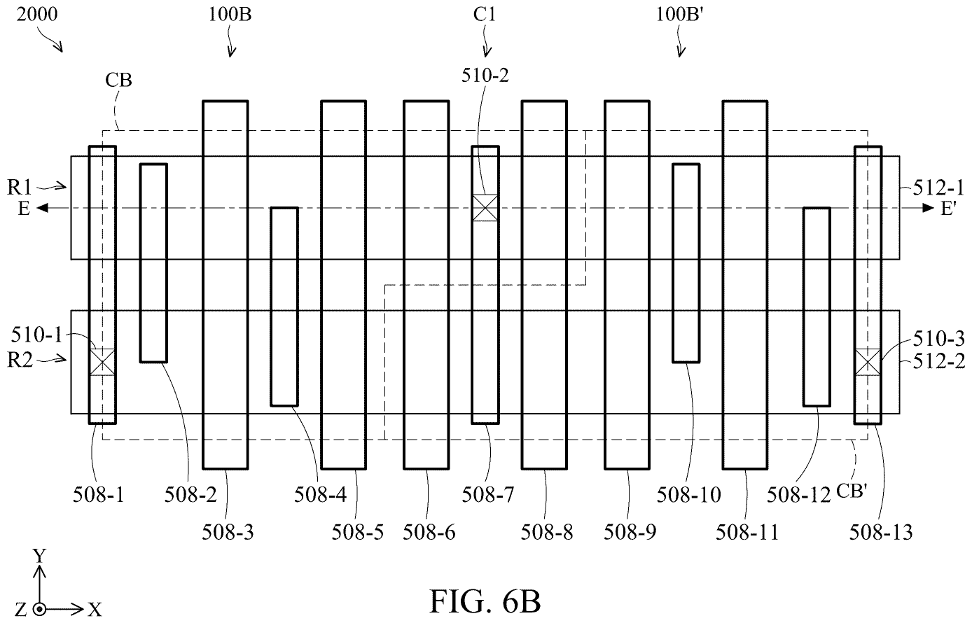

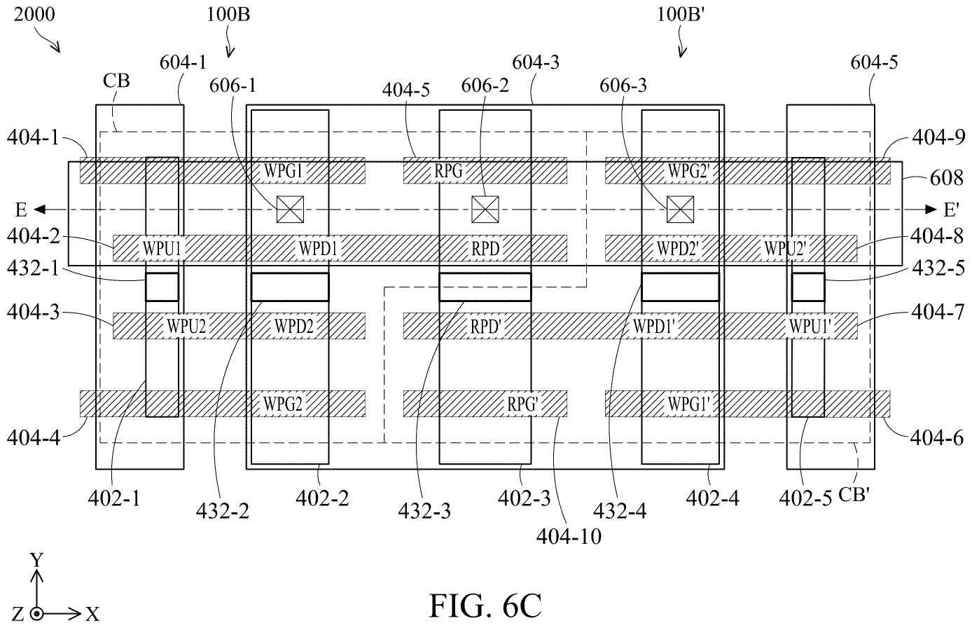

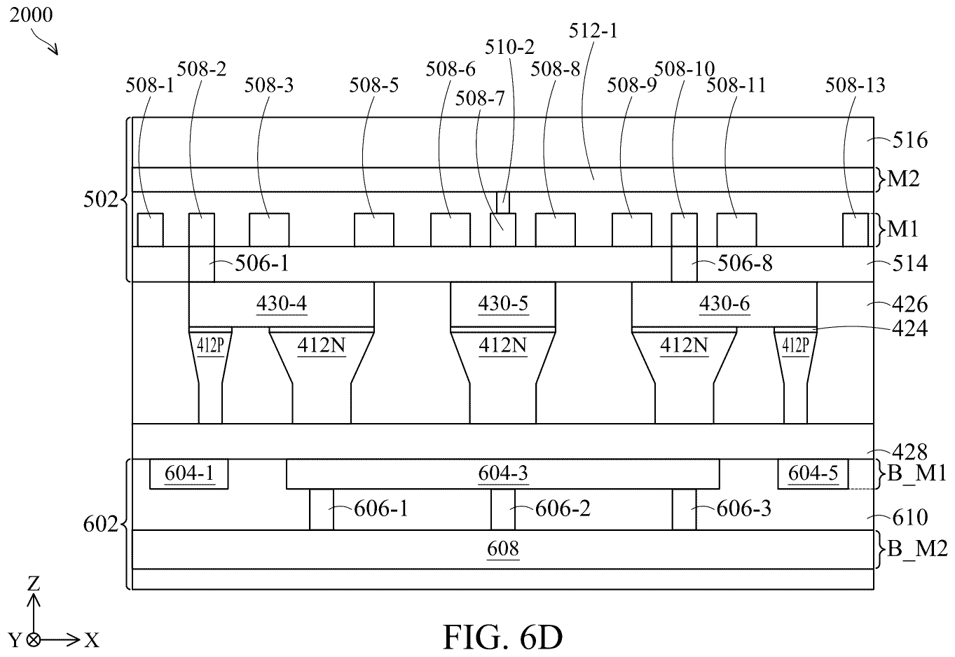

FIGS. 6A to 6C illustrate top views (or layouts) of features in a device region, a front-side interconnection structure, and a back-side interconnection structure of two adjacent SRAM cells 100B and 100B′ in a portion of an array 2000 that can be one embodiment of the SRAM cells 100 implemented in the memory region 20, in accordance with some alternative embodiments of the present disclosure. FIG. 6D is an X-Z cross-sectional view of the array 2000 along a line E-E′ in FIGS. 6A to 6C, in accordance with some alternative embodiments of the present disclosure.

The SRAM cells 100B and 100B′ are similar to the SRAM cells 100A and 100A′ discussed above, except that the metal conductors 604-2 and 604-4 serving as the VSS lines under (or at the back-side of) the transistors in the SRAM cells 100A and 100A′ are omitted. More specifically, the metal conductor 604-2 and 604-4 are not formed, and the metal conductor 604-3 shown in FIGS. 6A to 6D also serves the function of the metal conductor 604-2 and 604-4. As shown in FIGS. 6C and 6D, the metal conductor 604-3 extends in the X-direction to overlap the active areas 402-2, 402-3, and 402-4. The metal conductor 604-3 is electrically connected to the source/drain feature 412N shared by the WPD transistor WPD1 and WPD2 through the source/drain contact 432-2, is electrically connected to the source/drain feature 412N shared by the RPD transistors RPD and RPD′ through the source/drain contact 432-3, and is electrically connected to the source/drain feature 412N shared by the WPD transistor WPD1′ and WPD2′ through the source/drain contact 432-4, as shown in FIGS. 6C and 6D. The metal conductor 608 is electrically connected to the metal conductor 604-3 through the via 606-1, 606-2, and 606-3. As such, the metal conductor 604-3 shown in FIGS. 6A to 6D has a larger area to have low resistance than that shown in FIGS. 5A to 5G. The total resistance of the metal conductors 604-3 and 608 for power mesh are reduced, thereby improving the performance of the array 2000.

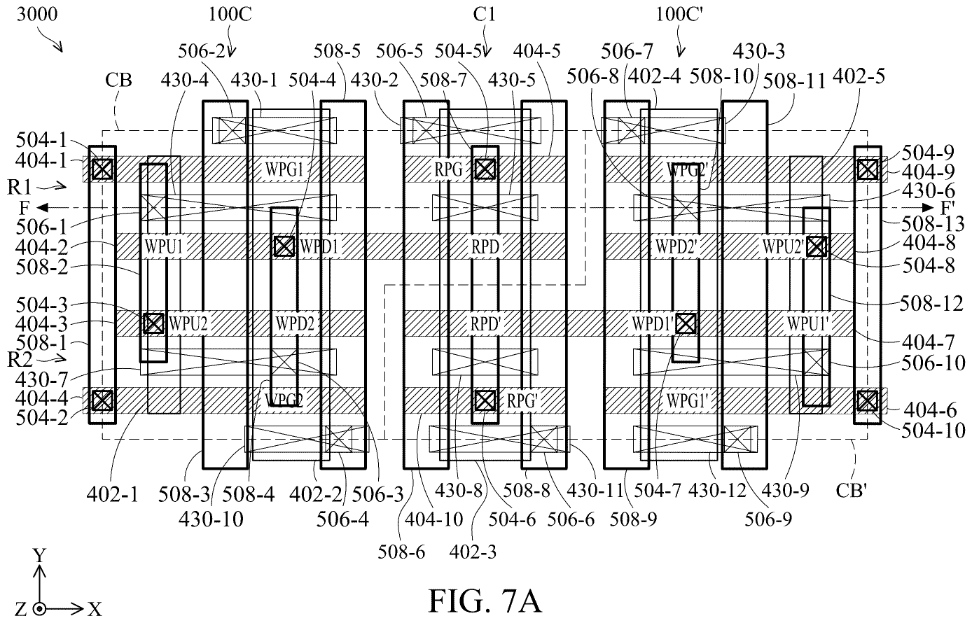

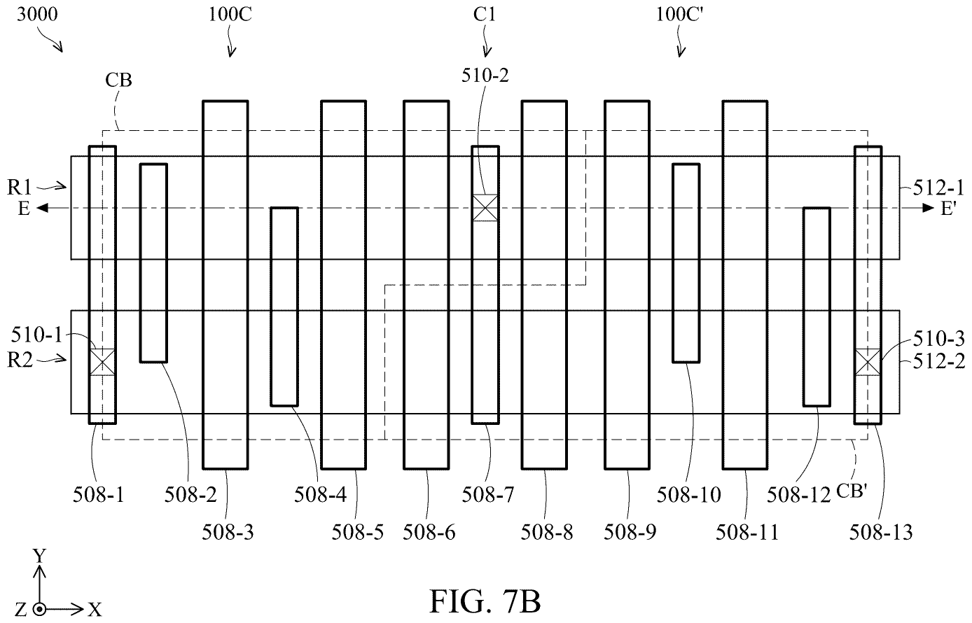

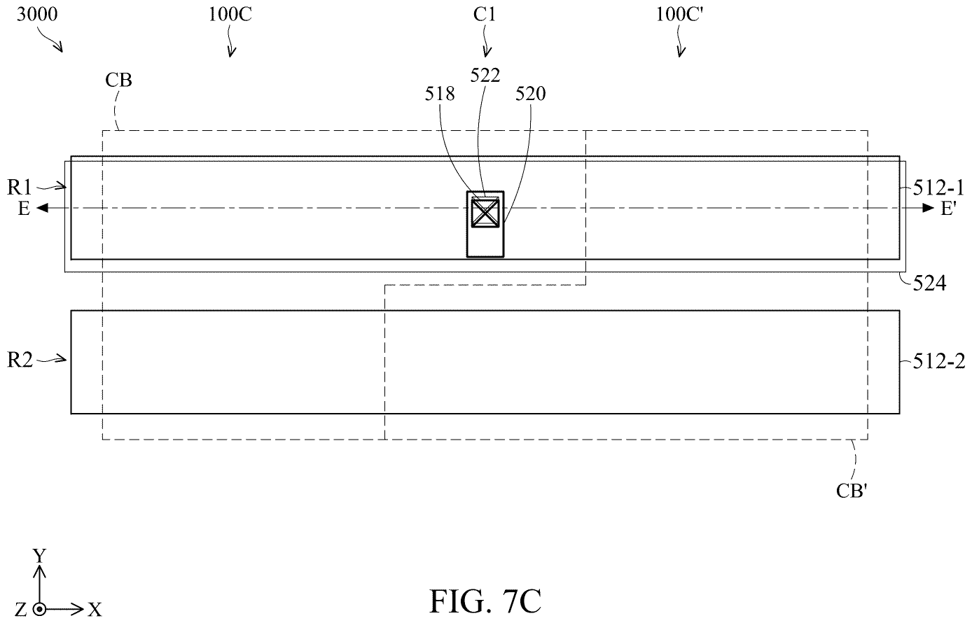

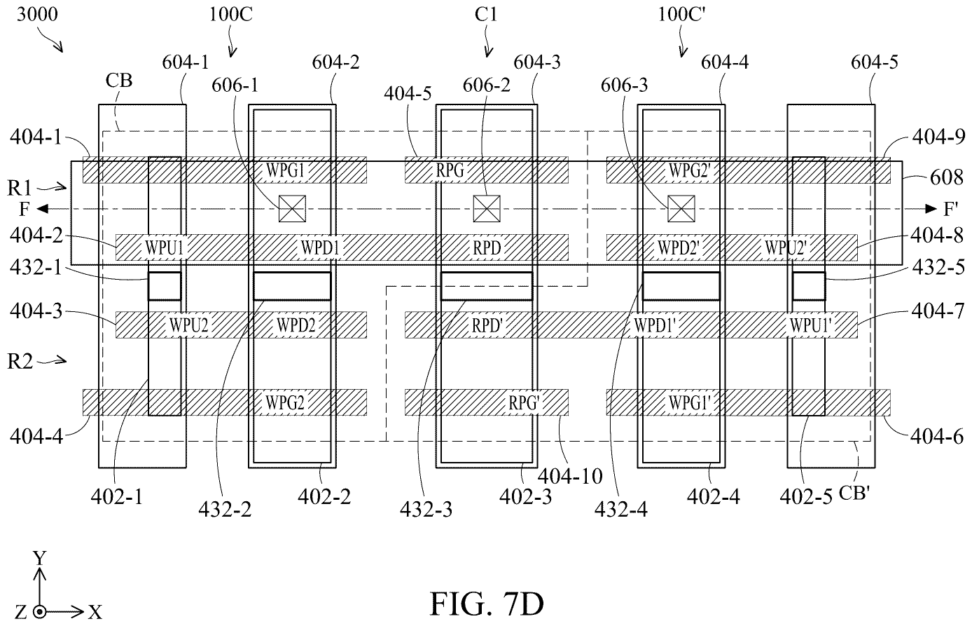

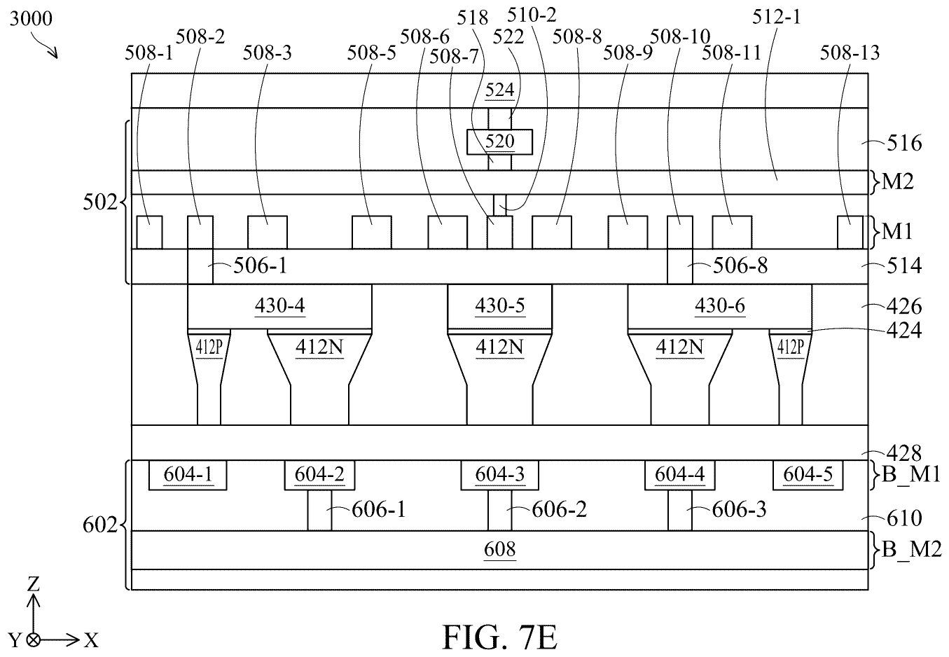

FIGS. 7A to 7D illustrate top views (or layouts) of features in a device region, a front-side interconnection structure, and a back-side interconnection structure of two adjacent SRAM cells 100C and 100C′ in a portion of an array 3000 that can be one embodiment of the SRAM cells 100 implemented in the memory region 20, in accordance with some alternative embodiments of the present disclosure. FIG. 7E is an X-Z cross-sectional view of the array 3000 along a line F-F′ in FIGS. 7A to 7D, in accordance with some alternative embodiments of the present disclosure.

FIG. 7A illustrates the features in the device region (including transistors) and the front-side interconnection structure including the metal conductors in the first metal layer (M1), and vias (V0, F_VG) vertically between the features and the first metal layer (M1). FIG. 7B illustrates the front-side interconnection structure including metal conductors in the first metal layer (M1) and the second metal layer (M2), and vias (V2) vertically between the first metal layer (M1) and the second metal layer (M2). FIG. 7C illustrates the front-side interconnection structure including metal conductors in the second metal layer (M2), the third metal layer (M3), and the fourth metal layer (M4), and a via (V2) vertically between the second metal layer (M2) and the third metal layer (M3) and a via (V3) vertically between the third metal layer (M3) and the fourth metal layer (M4). FIG. 7D illustrates the back-side interconnection structure including the metal conductors in the second metal layer (B_M1) and the third metal layer (B_M2), and vias (B_V1) vertically between the second metal layer (B_M1) and the third metal layer (B_M2).

The SRAM cells 100C and 100C′ are similar to the SRAM cells 100A and 100A′ discussed above, except that the front-side interconnection structure 502 of the array 3000 further includes a via 518, a metal conductor 520, a via 522, and a metal conductor 524 in the IMD layer 516, which are over (or at the front-side of) the transistors in the SRAM cells 100C and 100C′ (e.g., the WPG transistors WPG1, WPG2, WPG1′, and WPG2′, the WPD transistors WPD1, WPD2, WPD1′, and WPD2′, the WPU transistors WPU1, WPU2, WPU1′, and WPU2′, the RPG transistors RPG and RPG′, and the RPD transistors RPD and RPD′).

The metal conductors 520 and 524 are respectively in the (front-side) metal layers M3 and M4, as discussed above. The metal layer M3 is over the metal layer M2 and the metal layer M4 is over the metal layer M3, and thus the metal conductor 520 is over the metal conductors 512 and the metal conductor 524 is over the metal conductor 520. As show in FIGS. 7A to 7C, the metal conductor 520 extends lengthwise in the Y-direction, and the metal conductors 524 extends lengthwise in the X-direction.

The via 518 is vertically between and electrically connected to the metal conductor 512-1 and the metal conductor 520. The via 522 is vertically between and electrically connected to the metal conductor 520 and the metal conductor 524. In some embodiments, the vias 518 and 522 may have a square shape in the top view. In other embodiments, the vias 518 and 522 may have a circular shape in the top view. The via 518 and the via 522 may be respectively similar to the via V2 and the via V3 discussed above. The via 518 and the via 522, the metal conductors 520 and 524 may also be referred to as front-side vias and front-side metal conductors, respectively.

In some embodiments, the metal conductor 524 also serves as the read word-line RWL discussed above that controls and electrically connected to the gate structures (more specifically, the gate electrodes) of the RPG transistors. More specifically, the metal conductor 524 serves as the read word-line RWL shared by the SRAM cells 100A and 100A′. As shown in FIGS. 7A to 7D, for the SRAM cells 100A and 100A′, the metal conductor 524 is electrically connected to the metal conductor 512-1 serving as the read word-line RWL through the via 522, the metal conductor 520, and the via 518.

Therefore, it can be seen as that the metal conductor 524 and the metal conductor 512-1 electrically connected with each other in parallel to serve as the read word-line RWL, such that the total resistance of the metal conductors 524 and 512-1 are reduced, thereby improving the performance of the array 3000. In some embodiments, the metal conductor 524 may be referred to as read word-line conductor. In some embodiments, the metal conductor 520 may be referred to as read word-line landing pad.

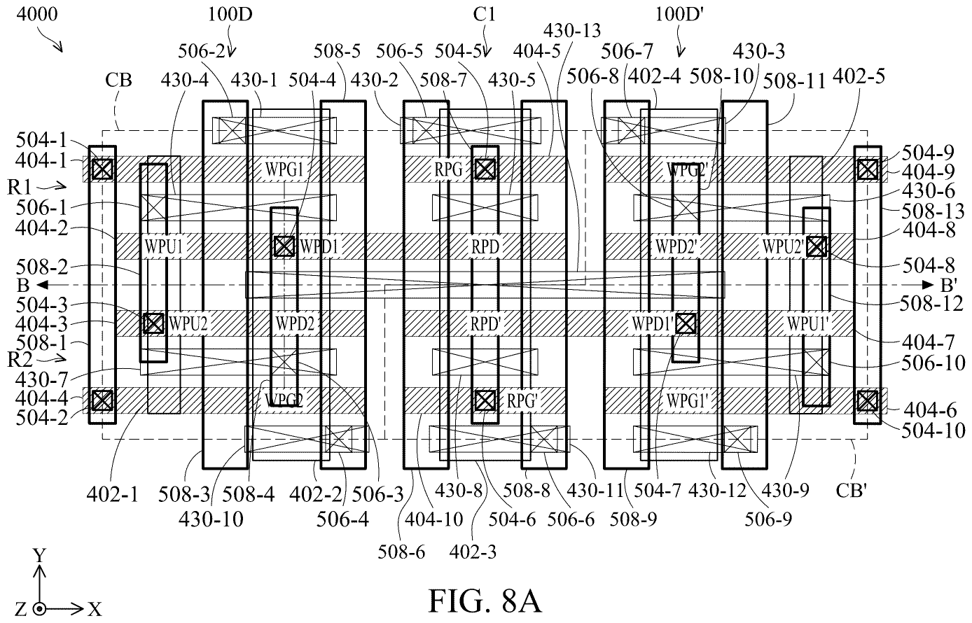

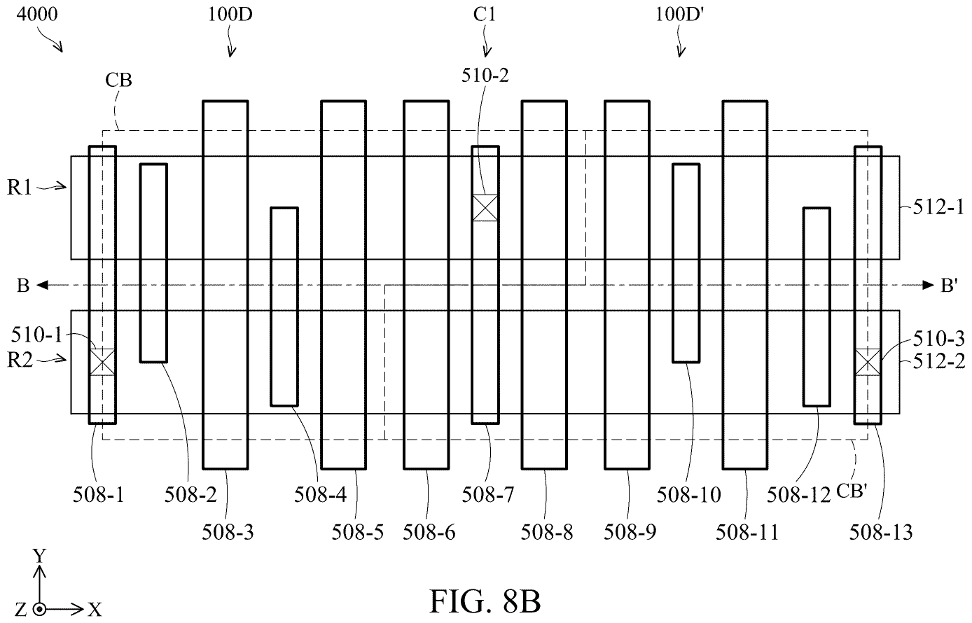

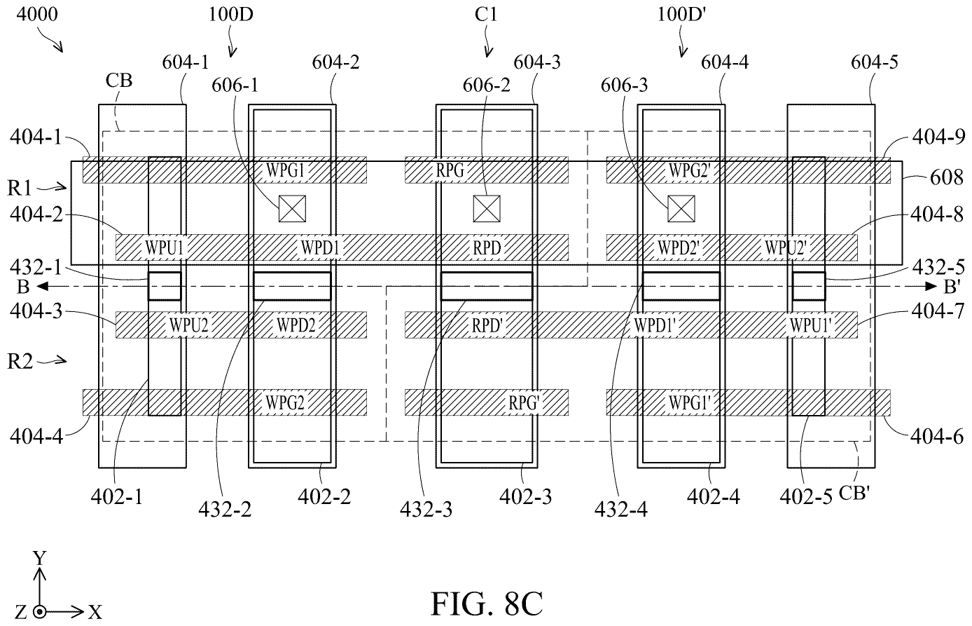

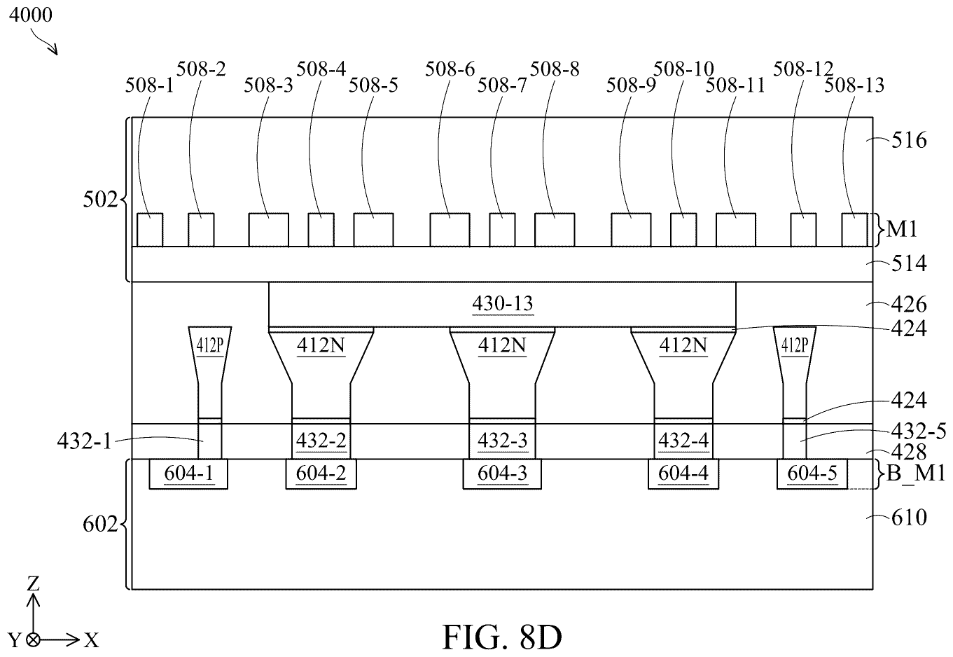

FIGS. 8A to 8C illustrate top views (or layouts) of features in a device region, a front-side interconnection structure, and a back-side interconnection structure of two adjacent SRAM cells 100D and 100D′ in a portion of an array 4000 that can be one embodiment of the SRAM cells 100 implemented in the memory region 20, in accordance with some alternative embodiments of the present disclosure. FIG. 8D is an X-Z cross-sectional view of the array 4000 along a line G-G′ in FIGS. 8A to 8C, in accordance with some alternative embodiments of the present disclosure.

The SRAM cells 100D and 100D′ are similar to the SRAM cells 100A and 100A′ discussed above, except that the SRAM cells 100D and 100D′ further include a source/drain contact 430-13. As shown in FIGS. 8A and 8D, the source/drain contact 430-13 extends lengthwise in the X-direction. In the top view, as shown in FIG. 8A, the source/drain contact 430-13 lengthwise overlaps the cell boundaries CB and CB′. In the top view, the source/drain contact 430-13 is between the gate structures 404-2 and 404-3, between the gate structures 404-2 and 404-7, and between the gate structures 404-7 and 404-8 (or between the write-port PD transistors WPD1 and WPD2, between the read-port PD transistors RPD and RPD′, and between the write-port PD transistors WPD1′ and WPD2′) in the Y-direction. The source/drain contact 430-8 is over and electrically connected to the source/drain feature 412N shared by the write-port PD transistor WPD1 and WPD2, the source/drain feature 412N shared by the read-port PD transistors RPD and RPD′, and the source/drain feature 412N shared by the write-port PD transistor WPD1′ and WPD2′.

It is noted that no metal conductor in the front-side interconnection structure 502 is designed over and electrically connected to the source/drain contact 430-13. In other words, the ILD layer 514 fully covers and is in contact with a top surface of the source/drain contact 430-13, as shown in FIG. 8D. The source/drain contact 430-13 is used for connecting the metal conductors 604-2, 604-3, and 604-4 together through the source/drain contact 430-13, the source/drain feature 412N shared by the write-port PD transistor WPD1 and WPD2, the source/drain feature 412N shared by the read-port PD transistors RPD and RPD′, and the source/drain feature 412N shared by the write-port PD transistor WPD1′ and WPD2′, such that it can be seen as that the metal conductors 604-2, 604-3, and 604-4 for VSS lines are electrically connected with each other in parallel, thereby the total resistance of the metal conductors 604-2, 604-3, and 604-4 for VSS lines are reduced. As such, the performance of the array 4000 is improved.

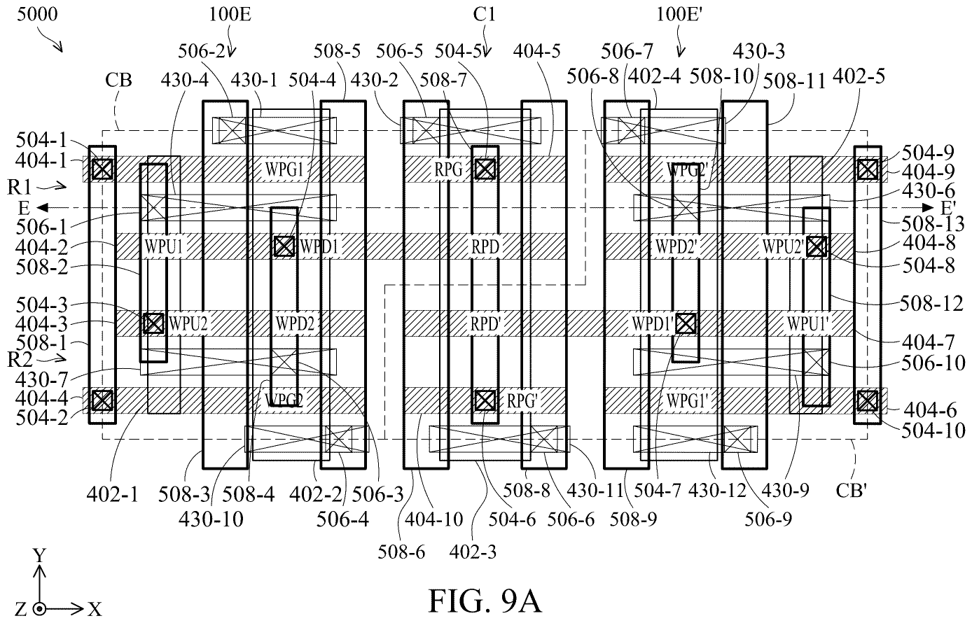

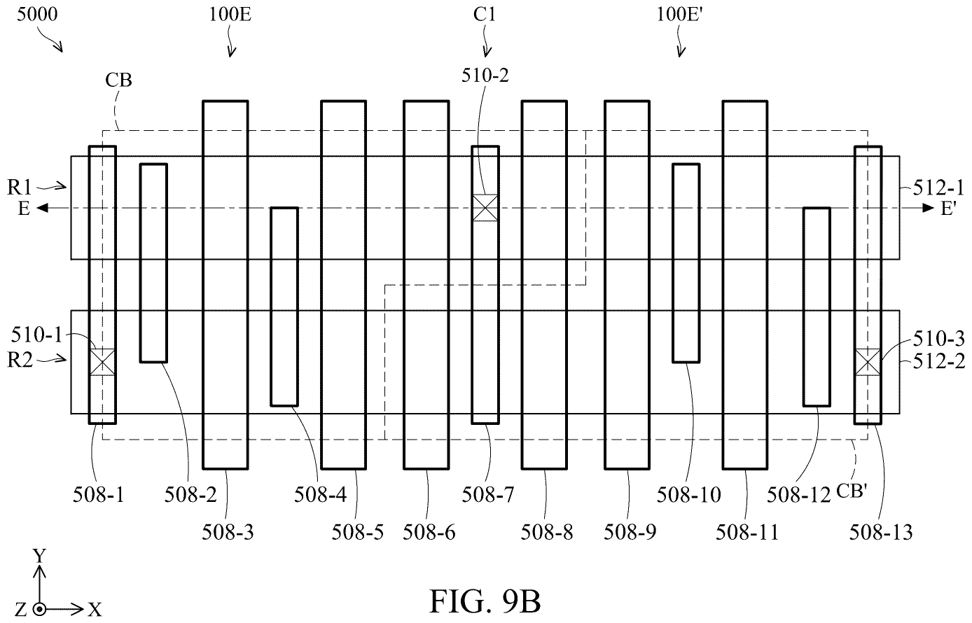

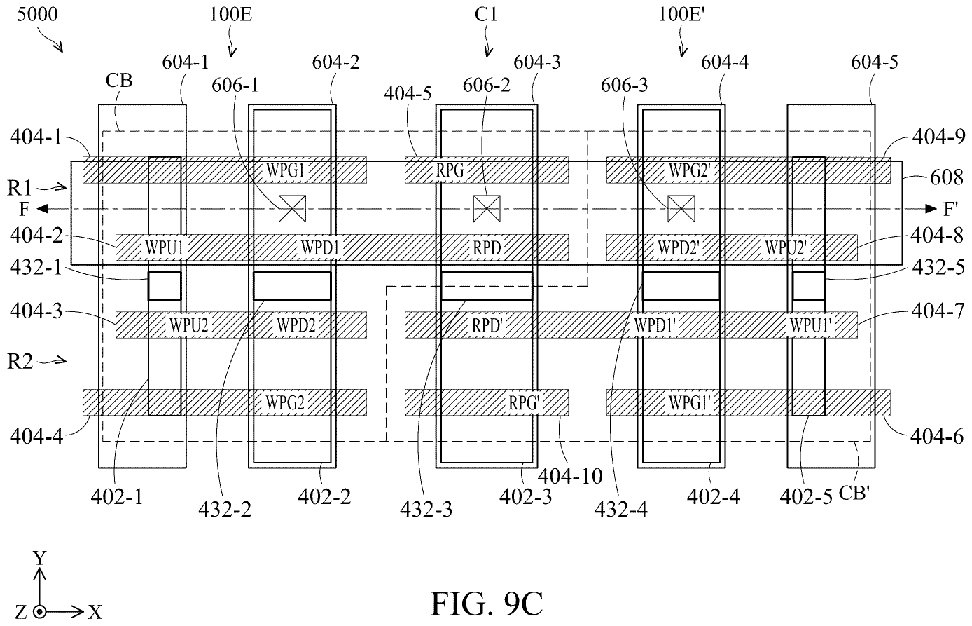

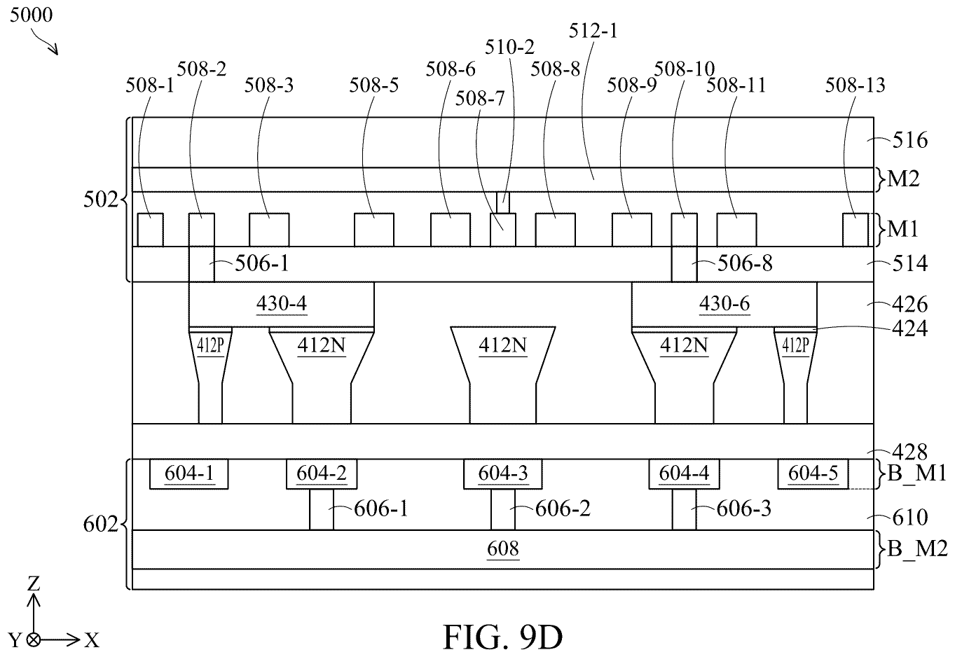

FIGS. 9A and 9B illustrate top views (or layouts) of features in a device region, a front-side interconnection structure, and a back-side interconnection structure of two adjacent SRAM cells 100E and 100E′ in a portion of an array 5000 that can be one embodiment of the SRAM cells 100 implemented in the memory region 20, in accordance with some alternative embodiments of the present disclosure. FIG. 9D is an X-Z cross-sectional view of the array 5000 along a line H-H′ in FIGS. 9A to 9C, in accordance with some alternative embodiments of the present disclosure.

The SRAM cells 100E and 100E′ are similar to the SRAM cells 100A and 100A′ discussed above, except that the source/drain contacts 430-5 and 430-8 are omitted. Referring back to FIGS. 5A to 5G, the source/drain contact 430-5 is over and electrically connected to the source/drain feature 412N shared by the RPG transistor RPG and the RPD transistor RPD, and the source/drain contacts 430-8 is over and electrically connected to the source/drain feature 412N shared by the RPG transistor RPG′ and the RPD transistor RPD′. Furthermore, the ILD layer 514 fully covers and is in contact with top surfaces of the source/drain contacts 430-5 and 430-8. Such configuration in the embodiments herein is more suitable for existing processes for the SRAM cell.

The source/drain contacts 430-5 and 430-8 shown in FIGS. 5A to 5G are not used for connection of the SRAM cells. In some embodiments, the source/drain contacts 430-5 and 430-8 are omitted. Therefore, as shown in FIGS. 9A to 9D, the ILD layer 426 fully covers and in contact with top surfaces of the source/drain feature 412N shared by the RPG transistor RPG and the RPD transistor RPD and the source/drain feature 412N shared by the RPG transistor RPG′ and the RPD transistor RPD′. As such, the contact-to-gate parasitic capacitance of the array 5000 is reduced, thereby improving the performance of the array 5000.

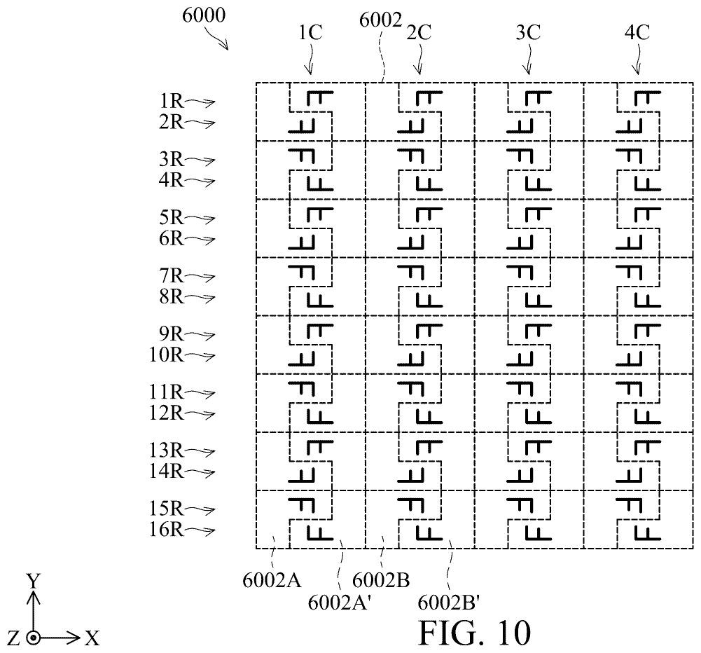

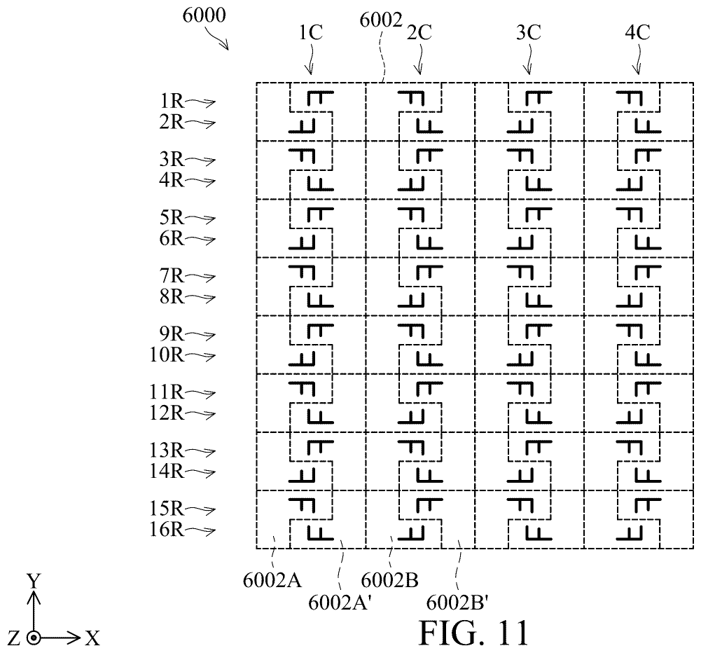

FIGS. 10 and 11 each illustrates one embodiment of a portion of the array 6000, in accordance with some embodiments of the present disclosure. The array 6000 shown in FIGS. 10 and 11 has SRAM cells 6002 arranged with four columns 1C to 4C and sixteen rows 1R to 16R. As discussed above, in every column, the adjacent two SRAM cells 6002 respectively in the adjacent two rows are abutted together. The structures of the abutted two SRAM cells 6002 are rotational symmetry by a rotation of 180 degrees. For example, the structure of SRAM cell 6002A is symmetric to the structure of SRAM cell 6002A′ by a rotation of 180 degrees, as shown in FIGS. 10 and 11. The structure of the SRAM cell 6002 are the same as the structure of the SRAM cells discussed above, such as the structure show in FIGS. 5A to 5G. For example, the structure of the SRAM cells 6002A and 6002A′ are the same as that of the SRAM cells 100A and 100A′. Further, referring to FIG. 10, the configuration and structure of the SRAM cells 6002 in each column are the same. More specifically, the configurations and structures of the SRAM cells 6002A and 6002A′ in column 1C are respectively the same as that of the SRAM cells 6002B and 6002B′ in column 2C.

In addition, referring to FIG. 11, the configuration and structure of the SRAM cells 6002 in the adjacent two columns are mirror symmetry. For example, the configuration and structure of the SRAM cell 6002A in column 1C are a mirror image of that of SRAM cell 6002B′ in column 2C with respect to an axis along the Y-direction (i.e., Y-axis); and the configuration and structure of the SRAM cell 3002A′ in column 1C are a mirror image of that of SRAM cell 3002B in column 2C with respect to the axis.

The embodiments disclosed herein relate to semiconductor devices, and more particularly to semiconductor devices including a metal conductor for the read bit-line that is shared by two SRAM cells in adjacent two rows of an SRAM array, in which the metal conductor is in the lowest metal layer (the metal layer M1), that can improve cell performance of the SRAM cells. Furthermore, the present embodiments provide one or more of the following advantages. The metal conductors for write word-line and read word-line in the higher metal layers may have a wider width to provide a lower circuit resistance, which improves the performance of the SRAM cells, such as RC delay. In addition, the metal conductors for VDD lines and VSS lines are disposed in the back-side interconnection structure under the SRAM cells to relieve the space at the front-side interconnection structure. The metal conductors for VDD lines and VSS lines are also in the lowest metal layer (the metal layer B_M1) to have lower capacitance, thereby improving the performance of the semiconductor devices.

Thus, one of the embodiments of the present disclosure describes a semiconductor device that includes a first static random access memory (SRAM) cell having a first L-shaped cell boundary, a first metal layer over the first SRAM cell, and a second metal layer under the first SRAM cell. The first SRAM cell includes a first write-port pull-up (WPU) transistor and a second WPU transistor arranged in a Y-direction, a first write-port pull-down (WPD) transistor, a second WPD transistor, a first write-port pass-gate (WPG) transistor, and a second WPG transistor arranged in the Y-direction, and a first read-port pull-down (RPD) transistor and a first read-port pass-gate (RPG) transistor arranged in the Y-direction. The first metal layer includes a first read bit-line (RBL) conductor connected to a source/drain feature of the first RPG transistor. The second metal layer includes a first VDD conductor connected to a source/drain feature shared by the first WPU transistor and the second WPU transistor.

In another of the embodiments, discussed is a semiconductor device including a first transistor cell having a first L-shape cell boundary, a first active area having a first channel layer with a first width in a first direction, first source/drain features attached and electrically connected to the first channel layer, a second active area having a second channel layer with a second width in the first direction, second source/drain features attached and electrically connected to the second channel layer. The dimensions of top surfaces of the first source/drain features and the second source/drain features in the first direction are greater than dimensions of bottom surfaces of the first source/drain features and the second source/drain features in the first direction. The first width is different from the second width, and at least two first back-side metal conductors are electrically connected to the first transistor cell.

In another of the embodiments, discussed is a semiconductor device including a first memory cell having a first non-rectangular cell boundary, a second memory cell having a second non-rectangular cell boundary, a first read bit-line (RBL) conductor and a second RBL conductor, and a first VSS conductor. The first memory cell includes a first write-port pull-up (WPU) transistor and a second WPU transistor sharing a first active area extending in a Y-direction, a first write-port pull-down (WPD) transistor, a second WPD transistor, a first write-port pass-gate (WPG) transistor, and a second WPG transistor sharing a second active area extending in the Y-direction, and a first read-port pull-down (RPD) transistor and a first read-port pass-gate (RPG) transistor sharing a third active area extending in the Y-direction. The second non-rectangular cell boundary is abutted to the first non-rectangular cell boundary in an X-direction to form a rectangular shape. The second memory cell includes a third WPU transistor and a fourth WPU transistor sharing a fourth active area extending in the Y-direction, a third WPD transistor, a fourth WPD transistor, a third WPG transistor, and a fourth WPG transistor sharing a fifth active area extending in the Y-direction, and a second RPD transistor and a second RPG transistor sharing the third active area. The first RBL conductor and the second RBL conductor are in a first metal layer over the first memory cell and the second memory cell. The first RBL conductor is electrically connected to a source/drain feature of the first RPG transistor and the second RBL conductor is electrically connected to a source/drain feature of the second RPG transistor. The first VSS conductor is in a second metal layer under the first memory cell and the second memory cell. The VSS conductor lengthwise overlaps the third active area in a top view.

In yet another of the embodiments, discussed is a semiconductor device that includes a first static random access memory (SRAM) cell, a second SRAM cell abutted to the first SRAM cell in an X-direction, a first metal layer over the first SRAM cell and the second SRAM cell, a second metal layer over the first metal layer, and a third metal layer under the first SRAM cell and the second SRAM cell. The first SRAM cell includes a first write-port pull-up (WPU) transistor and a second WPU transistor arranged in a Y-direction, a first write-port pull-down (WPD) transistor, a second WPD transistor, a first write-port pass-gate (WPG) transistor, and a second WPG transistor arranged in the Y-direction, and a first read-port pull-down (RPD) transistor and a first read-port pass-gate (RPG) transistor arranged in the Y-direction. The second SRAM cell includes a third WPU transistor and a fourth WPU transistor arranged in the Y-direction, a third WPD transistor, a fourth WPD transistor, a third WPG transistor, and a fourth WPG transistor arranged in the Y-direction, and a second RPD transistor and a second RPG transistor arranged with the first RPD transistor and the first RPG transistor in the Y-direction. The first metal layer includes a first read bit-line (RBL) conductor extending in the Y-direction and electrically connected to a source/drain feature of the first RPG transistor, and a second RBL conductor extending in the Y-direction and electrically connected to a source/drain feature of the second RPG transistor. The second metal layer includes a read word-line (RWL) conductor extending in the X-direction and shared by the first SRAM cell and the second SRAM cell, and a write word-line (WWL) conductor extending in the X-direction and shared by the first SRAM cell and the second SRAM cell. The third metal layer includes a first VSS conductor extending in the Y-direction and electrically connected to a source/drain feature shared by the first RPD transistor and the second RPD transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor cell having a first L-shape cell boundary;
a first active area having a first channel layer with a first width in a first direction;
first source/drain features attached and electrically connected to the first channel layer;
a second active area having a second channel layer with a second width in the first direction; and
second source/drain features attached and electrically connected to the second channel layer,
wherein dimensions of top surfaces of the first source/drain features and the second source/drain features in the first direction are greater than dimensions of bottom surfaces of the first source/drain features and the second source/drain features in the first direction,
wherein the first width is different from the second width, and at least two first back-side metal conductors are electrically connected to the first transistor cell.

2. The semiconductor device of claim 1, further comprising:
a second transistor cell having a second L-shape cell boundary abutted to the first L-shaped cell boundary, wherein the first L-shaped cell boundary and the second L-shaped cell boundary are rotational symmetry;
a third active area having a third channel layer with the first width; and
a fourth active area having a fourth channel layer with the second width,
wherein at least two second back-side metal conductors electrically connected to the second transistor cell.

3. The semiconductor device of claim 2,
wherein the first back-side metal conductors comprises a first VDD conductor under and overlapping the first active area and a first VSS conductor under and overlapping the second active area,
wherein the second back-side metal conductors comprises a second VDD conductor under and overlapping the third active area and a second VSS conductor under and overlapping the fourth active area.

4. The semiconductor device of claim 3, further comprising:
a fifth active area shared by the first transistor cell and the second transistor cell, wherein the fifth active area has a fifth channel layer with a third width in the first direction, wherein the third width is different from the first width and the second width; and
a third VSS conductor under and overlapping the fifth active area, wherein the third VSS conductor is electrically connected to the first transistor cell and the second transistor cell.

5. The semiconductor device of claim 4, wherein the third width is greater than the first width and the second width, and the second width is greater than the first width.

6. The semiconductor device of claim 4,
wherein the first transistor cell further comprises:
a first write-port pull-up (WPU) transistor and a second WPU transistor sharing the first active area;
a first write-port pull-down (WPD) transistor, a second WPD transistor, a first write-port pass-gate (WPG) transistor, and a second WPG transistor sharing the second active area; and
a first read-port pull-down (RPD) transistor and a first read-port pass-gate (RPG) transistor sharing the fifth active area,
wherein the second transistor cell further comprises:
a third WPU transistor and a fourth WPU transistor sharing the third active area;
a third WPD transistor, a fourth WPD transistor, a third WPG transistor, and a fourth WPG transistor sharing the fourth active area; and
a second RPD transistor and a second RPG transistor sharing the fifth active area.

7. The semiconductor device of claim 4, further comprising:
a first read bit-line (RBL) conductor over and electrically connected to the first RPG transistor; and
a second RBL conductor connected over and electrically connected to the second RPG transistor.

8. The semiconductor device of claim 7, further comprising:
a first read word-line (RWL) conductor over the first RBL conductor and the second RBL conductor, wherein the first RWL conductor is electrically connected the first RPG transistor and the second RPG transistor; and
a write word-line (WWL) conductor over the first RBL conductor and the second RBL conductor, wherein the WWL conductor is electrically connected to the first WPG transistor, the second WPG transistor, the third WPG transistor, and the fourth WPG transistor.

9. The semiconductor device of claim 8, further comprising:
a second RWL conductor over and electrically connected to the first RWL conductor.

10. The semiconductor device of claim 6, further comprising:
a source/drain contact over and connected to a source/drain feature shared by the first WPD transistor and the second WPD transistor, a source/drain feature shared by the first RPD transistor and the second RPD transistor, and a source/drain feature shared by the third WPD transistor and the fourth WPD transistor; and
an inter-layer dielectric layer fully covering a top surface of the source/drain contact.

11. A semiconductor device, comprising:
a first memory cell having a first non-rectangular cell boundary, wherein the first memory cell comprises:
a first write-port pull-up (WPU) transistor and a second WPU transistor sharing a first active area extending in a Y-direction;
a first write-port pull-down (WPD) transistor, a second WPD transistor, a first write-port pass-gate (WPG) transistor, and a second WPG transistor sharing a second active area extending in the Y-direction; and
a first read-port pull-down (RPD) transistor and a first read-port pass-gate (RPG) transistor sharing a third active area extending in the Y-direction;
a second memory cell having a second non-rectangular cell boundary abutted to the first non-rectangular cell boundary in an X-direction to form a rectangular shape, wherein the second memory cell comprises:
a third WPU transistor and a fourth WPU transistor sharing a fourth active area extending in the Y-direction;
a third WPD transistor, a fourth WPD transistor, a third WPG transistor, and a fourth WPG transistor sharing a fifth active area extending in the Y-direction; and
a second RPD transistor and a second RPG transistor sharing the third active area;
a first read bit-line (RBL) conductor and a second RBL conductor in a first metal layer over the first memory cell and the second memory cell, wherein the first RBL conductor is electrically connected to a source/drain feature of the first RPG transistor and the second RBL conductor is electrically connected to a source/drain feature of the second RPG transistor; and
a first VSS conductor in a second metal layer under the first memory cell and the second memory cell, wherein the VSS conductor lengthwise overlaps the third active area in a top view.

12. The semiconductor device of claim 11, further comprising:
a first write bit-line-bar (WBLB) conductor in the first metal layer and electrically connected to a source/drain feature of the second WPG transistor; and
a second WBLB conductor in the first metal layer and electrically connected to a source/drain feature of the fourth WPG transistor,
wherein the first RBL conductor and the second RBL conductor are between the first WBLB conductor and the second WBLB conductor in the X-direction.

13. The semiconductor device of claim 11, further comprising:
a first VDD conductor in the second metal layer and lengthwise overlapping the first active area in the top view; and
a second VDD conductor in the second metal layer and lengthwise overlapping the fourth active area in the top view.

14. The semiconductor device of claim 11, wherein the first VSS conductor overlaps the second active area and the fifth active area in the top view.

15. The semiconductor device of claim 11, further comprising:
an inter-layer dielectric layer fully covering and in contact with top surfaces of a source/drain feature shared by the first RPD transistor and the first RPG transistor and a source/drain feature shared by the second RPD transistor and the second RPG transistor.

16. The semiconductor device of claim 11, further comprising:
a first source/drain contact over and in contact with a source/drain feature shared by the first RPD transistor and the first RPG transistor;
a second source/drain contact over and in contact with a source/drain feature shared by the second RPD transistor and the second RPG transistor; and
an inter-layer dielectric layer fully covering and in contact with top surfaces of the first source/drain contact and the second source/drain contact.

17. A semiconductor device, comprising:
a first static random access memory (SRAM) cell, comprising:
a first write-port pull-up (WPU) transistor and a second WPU transistor arranged in a Y-direction;
a first write-port pull-down (WPD) transistor, a second WPD transistor, a first write-port pass-gate (WPG) transistor, and a second WPG transistor arranged in the Y-direction; and
a first read-port pull-down (RPD) transistor and a first read-port pass-gate (RPG) transistor arranged in the Y-direction;
a second SRAM cell abutted to the first SRAM cell in an X-direction, comprising:
a third WPU transistor and a fourth WPU transistor arranged in the Y-direction;
a third WPD transistor, a fourth WPD transistor, a third WPG transistor, and a fourth WPG transistor arranged in the Y-direction; and
a second RPD transistor and a second RPG transistor arranged with the first RPD transistor and the first RPG transistor in the Y-direction,
a first metal layer over the first SRAM cell and the second SRAM cell, comprising:
a first read bit-line (RBL) conductor extending in the Y-direction and electrically connected to a source/drain feature of the first RPG transistor; and
a second RBL conductor extending in the Y-direction and electrically connected to a source/drain feature of the second RPG transistor;
a second metal layer over the first metal layer, comprising:
a read word-line (RWL) conductor extending in the X-direction and shared by the first SRAM cell and the second SRAM cell; and
a write word-line (WWL) conductor extending in the X-direction and shared by the first SRAM cell and the second SRAM cell; and
a third metal layer under the first SRAM cell and the second SRAM cell, comprising:
a first VSS conductor extending in the Y-direction and electrically connected to a source/drain feature shared by the first RPD transistor and the second RPD transistor.

18. The semiconductor device of claim 17, wherein the first VSS conductor extends in the X-direction and is electrically connected to a source/drain feature shared by the first WPD transistor and the second WPD transistor and a source/drain feature shared by the third WPD transistor and the fourth WPD transistor.

19. The semiconductor device of claim 17, further comprising:
a fourth metal layer under the third metal layer, wherein the fourth metal layer comprises a second VSS conductor extending in the X-direction and electrically connected to the first VSS conductor.

20. The semiconductor device of claim 17, further comprising:
a source/drain contact extending in the X-direction and over a source/drain feature shared by the first WPD transistor and the second WPD transistor, a source/drain feature shared by the first RPD transistor and the second RPD transistor, and a source/drain feature shared by the third WPD transistor and the fourth WPD transistor; and
an inter-layer dielectric layer fully covering and in contact with a top surface of the source/drain contact.
